(19) United States
(12) Patent Application Publication
(10) Pub. No.: US 2012/0229953 A1
(43) Pub. Date: Sep. 13, 2012

(54) LEAD-FREE PIEZOELECTRIC PORCELAIN COMPOSITION, PIEZOELECTRIC CERAMIC COMPONENT FORMED USING THE COMPOSITION, AND PROCESS FOR PRODUCING PIEZOELECTRIC CERAMIC COMPONENT

(75) Inventors: Keiichi Hatano, Takasaki-shi (JP); Keisuke Kobayashi, Takasaki-shi (JP); Tomoya Hagiwara, Takasaki-shi (JP); Hiroyuki Shimizu, Takasaki-shi (JP); Yutaka Doshida, Takasaki-shi (JP)

(73) Assignee: TAIYO YUDEN CO., LTD., Taito-ku, Tokyo (JP)

(21) Appl. No.: 13/510,261

(22) PCT Filed: Sep. 21, 2010
(86) PCT No.: PCT/JP2010/066302

§ 371 Date: May 16, 2012

(30) Foreign Application Priority Data
Nov. 18, 2009 (JP) 2009-262489
May 20, 2010 (JP) 2010-115961

(51) Int. Cl. H01L 41/187; H01G 4/12; H01L 41/22

(52) U.S. Cl. 361/321.4; 29/25.35; 252/62.9 R

(57) ABSTRACT

Provided is an alkali-niobate-based piezoelectric porcelain composition which has a crystal-structure transition point in the range of operation guarantee temperatures and which, despite this, is inhibited from abruptly changing in capacitance. The piezoelectric porcelain composition comprises Li, Na, K, Nb, Ta, Sb, and O as major constituent elements and has an alkali-niobate-based perovskite structure. When the composition has an ABO₃ type perovskite structure as a unit lattice in which Z=1, the composition has a transition point at which the crystal structure changes from the monoclinic to the tetragonal system. Thus, the composition has a crystal-structure transition point at −50° C. to 150° C. so as to utilize the high piezoelectric effect produced by the MPB at the crystal-structure transition point and, despite this, has the feature of always satisfying ΔC>0.

### TECHNICAL FIELD

The present invention relates to a piezoelectric porcelain composition having an alkali-niobate-based perovskite structure and not containing lead, and piezoelectric ceramic component formed using such composition, such as piezoelectric sounding body, piezoelectric sensor, piezoelectric actuator, piezoelectric transformer, piezoelectric ultrasonic motor, as well as a process for producing such piezoelectric ceramic component.

### BACKGROUND ART

The principle of converting the electrical energy of a piezoelectric porcelain composition to mechanical energy or mechanical energy of the composition to electrical energy (piezoelectric effect) has been applied to many electronic devices.

Electronic devices that use this piezoelectric effect are specifically called “piezoelectric devices,” and electronic components having a piezoelectric porcelain composition used for these piezoelectric devices are called “piezoelectric ceramic components.”

Piezoelectric porcelain compositions that have been traditionally used for piezoelectric ceramic components that each constitute a piezoelectric device include, for example, a piezoelectric porcelain composition comprising two components of PbTiO₃ and PbZrO₃ and containing lead (hereinafter referred to as “PZT”), and piezoelectric porcelain composition comprising this PZT plus a third component such as Pb(Mg_{1/3}Nb_{2/3})O₃ and Pb(Zn_{1/3}Nb_{2/3})O₃.

Piezoelectric porcelain compositions whose main ingredient is PZT boast high piezoelectric characteristics and are used in almost all piezoelectric ceramic components currently in practical use.

However, the aforementioned piezoelectric porcelain compositions whose main ingredient is PZT contain Pb and therefore present problems of high environmental burdens such as volatilization of PbO in the production process.

For these reasons, piezoelectric porcelain compositions not containing lead or containing a reduced amount of lead have been desired. There have been active research efforts in recent years regarding piezoelectric porcelain compositions not containing lead, and among others, piezoelectric porcelain compositions having an alkali-niobate-based perovskite structure (hereinafter referred to as “AN-PV structure”) are shown to demonstrate piezoelectric effect equivalent to that of PZT, as disclosed in, for example, Non-patent Literatures 1 and 2.

The aforementioned piezoelectric porcelain compositions having an AN-PV structure are primarily constituted by such key ingredient elements as Li, Na, K, Nb, Ta, Sb and O. To be specific, they are expressed by the general formula {Liₓ[Na_{1-y}K_{y}]₁₋ₓ}ₐ{Nb_{1-z-w}Ta_{z}Sb_{w}}_{b}O₃ (wherein x, y, z, w, a and b each represent a mol ratio, where the specific ranges of mol ratios are 0≦x0.2, 0≦y≦1, 0≦z≦0.4, 0≦w≦0.2, a≧0.95 and b≦1.05). These piezoelectric porcelain compositions having an AN-PV structure are generally known to possess high piezoelectric characteristics (piezoelectric constant, electromechanical coupling coefficient, etc.) in the aforementioned ranges (refer to Patent Literatures 1 to 3).

One physical explanation of why the aforementioned piezoelectric porcelain compositions having an AN-PV structure demonstrate high piezoelectric characteristics is the presence of the morphotropic phase boundary (hereinafter abbreviated as “MPB”).

The MPB is a composition boundary where the crystal structure of a chemical compound changes, and it has been made clear that extremely high piezoelectric characteristics can be obtained in a zone where a MPB is expected to be present (refer to Patent Literature 4, Non-patent Literatures 1 to 4). With piezoelectric porcelain compositions having an AN-PV structure, a MPB is present as a result of adding Li, Ta, Sb, etc., as solid solutions in an appropriate manner to adjust the composition, thereby adjusting, to a temperature near room temperature, the transition point at which the crystal structure changes from the orthorhombic system to the tetragonal system, or from the monoclinic system with a molecular number of 2 or greater (Z≧2) to the tetragonal system. To be specific, the transition point at which the crystal structure changes from the orthorhombic system to the tetragonal system, or transition point at which the crystal structure changes from the monoclinic system of Z≧2 to the tetragonal system, exists between 200° C. and 350° C. for a piezoelectric porcelain composition having an AN-PV structure, or specifically [Na_{1-y}K_{y}]NbO₃ (0≦y≦1). Accordingly, it is necessary to add Li, Ta and Sb as solid solutions in an appropriate manner and lower the crystal-structure transition point to a range of −50° C. to 150° C., in order to adjust the MPB of the alkali-niobate-based piezoelectric porcelain composition to within a temperature zone where high piezoelectric characteristics are required of the piezoelectric device.

The process of adding Li, Ta and Sb as solid solutions in an appropriate manner to [Na_{1-y}K_{y}]NbO₃ as mentioned above has already been studied in detail by many researchers, and methods to change the aforementioned crystal-structure transition point by means of a solid solution process are already known. For example, Non-patent Literature 2 and Patent Literature 4 present an example of experiment where Li is added as a solid solution to Na_{0.5}K_{0.5}NbO₃, with a specific example shown to illustrate how the transition point at which the crystal structure changes from the orthorhombic system to the tetragonal system changes when x in Liₓ(Na_{0.5}K_{0.5})₁₋ₓNbO₃ is changed from 0 to 0.20. In Non-patent Literature 5, for example, a specific example is shown to illustrate how the transition point at which the crystal structure changes from the orthorhombic system to the tetragonal system changes with respect to a composition whose main phase is Na_{0.5}K_{0.5}NbO₃ and whose Nb is substituted with Ta. In Non-patent Literature 6, for example, an example of an experiment is presented where Li and Sb are added as solid solutions to a composition whose main phase is Na_{0.5}K_{0.5}NbO₃, with a specific example shown to illustrate how the transition point at which the crystal structure changes from the orthorhombic system to the tetragonal system changes when x in Liₓ(Na_{0.5}K_{0.5}Nb)₁₋ₓSbₓO₃ is changed from 0 to 0.10.

### BACKGROUND ART LITERATURES

### Non-Patent Literatures

Non-patent Literature 1: Nature, 432 (4), 2004, pp. 84-87
Non-patent Literature 2: Applied Physics Letters 85 (18), 2004, pp. 4121-4123
Non-patent Literature 3: Materials Letter 59, 2005, pp. 241-244
Non-patent Literature 4: Applied Physics Letters 88, 212908 (2006)
Non-patent Literature 5: Journal of Applied Physics 97, 114105 (2005)
Non-patent Literature 6: Journal of Applied Physics 101, 074111 (2007)

### Patent Literatures

Patent Literature 1: Japanese Patent Laid-open No. 2002-068835
Patent Literature 2: Japanese Patent Laid-open No. 2003-342069
Patent Literature 3: Japanese Patent Laid-open No. 2004-300012
Patent Literature 4: Japanese Patent Laid-open No. 2006-151796

### SUMMARY OF THE INVENTION

### Problems to Be Solved by the Invention

By lowering the crystal-structure transition point in an appropriate manner using the method mentioned above, a piezoelectric porcelain composition having an AN-PV structure and demonstrating high piezoelectric characteristics in a practical zone can be obtained. However, such piezoelectric porcelain composition having the AN-PV structure mentioned above has a crystal-structure transition point between −50° C. and 150° C., where the crystal structure changes from the orthorhombic system or monoclinic system of Z≧2 to the tetragonal system. When the crystal structure changes from the orthorhombic system or monoclinic system of Z≧2 to the tetragonal system, electrical characteristics change significantly.

This is because, generally to allow a piezoelectric porcelain composition to function as a piezoelectric body, a so-called polarization process is performed where an electric field is applied to control the domain orientation in the crystal grain to one direction. When such a polarization process is performed, the capacitance of the piezoelectric porcelain composition increases or decreases from the level before the polarization process according to the spontaneous polarization orientation which is specified by the crystal structure system and space group of the composition. This is because, following a polarization process, the domain orientation in each crystal grain constituting the piezoelectric porcelain composition is controlled in a different orientation if the crystal system and space group of the piezoelectric porcelain composition are different, and consequently the resulting crystal orientation depends on the crystal system and space group of the piezoelectric porcelain composition.

As for specific electrical characteristics, the rate of change in capacitance before and after polarization ΔC, calculated by (Cb−Ca)/Cb=ΔC, where Cb represents the capacitance before the polarization process and Ca represents the capacitance after the polarization process, generally takes a negative value smaller than 0 when the crystal structure is the orthorhombic system or monoclinic system of Z≧2, and ΔC generally takes a positive value greater than 0 when the crystal structure is the tetragonal system. For this reason, the capacitance changes significantly before and after the crystal-structure transition point as mentioned above.

Furthermore, the values of expressed piezoelectric characteristics also change significantly before and after the crystal-structure transition point as mentioned above, due to different orientations of domain control.

This means that, with a piezoelectric porcelain composition having an AN-PV structure and whose transition point at which the crystal structure changes from the orthorhombic system or monoclinic system of Z≧2 to the tetragonal system exists between −50° C. and 150° C., the capacitance changes suddenly at the crystal-structure transition point after the polarization process. This is caused by the spontaneous polarization orientation being different before and after the crystal-structure transition point due to different crystal systems and space groups, as mentioned above. A piezoelectric device using such a piezoelectric porcelain composition is subject to sudden change in capacitance due to temperature, and therefore the temperature range in which its operation is guaranteed becomes narrow. For example, if a piezoelectric porcelain composition having an AN-PV structure is used for a piezoelectric ceramic component or piezoelectric device whose operation must be guaranteed over a wide temperature range of −50° C. to 150° C. for automotive application, etc., the capacitance characteristics change significantly in this operating temperature zone, presenting practical problems such as circuit inconsistency occurring frequently. Also, as pointed out earlier, not only the capacitance but also piezoelectric characteristics change significantly before and after the transition point at which the crystal structure changes from the orthorhombic system or monoclinic system of Z≧2 to the tetragonal system, which presents serious practical problems in addition to circuit inconsistency because the amount of displacement occurring when the device is driven in the applicable operating temperature zone, for example, changes sensitively due to temperature.

One conceivable way to reduce such circuit inconsistency or temperature characteristics of the amount of displacement is to simply adjust the aforementioned crystal-structure transition point to outside the temperature range where the piezoelectric device operates. However, this naturally contradicts the design of piezoelectric porcelain compositions having an AN-PV structure whose purpose is to embody high piezoelectric characteristics using the MPB at the crystal-structure transition point, and therefore an entirely new design method had to be invented.

To overcome the aforementioned problems, the present invention embodies an entirely new piezoelectric porcelain composition having an AN-PV structure characterized by having its crystal-structure transition point within the guaranteed operating temperature range of, say, −50° C. to 150° C. in order to utilize the MPB at the crystal-structure transition point, while maintaining ΔC>0 at all times over the aforementioned guaranteed operating temperature range and reducing the temperature dependence of expressed piezoelectric characteristics, and by embodying such composition the present invention provides a piezoelectric porcelain composition wherein sudden change in capacitance and piezoelectric characteristics before and after the crystal-structure transition point are reduced, as well as various piezoelectric ceramic components and piezoelectric devices demonstrating piezoelectric effect whose operation can be guaranteed over a wide temperature range, which can ultimately substitute lead-based piezoelectric devices that contain PbO having high environmental burdens.

### Means for Solving the Problems

After studying in earnest to solve the aforementioned problems, the inventors of the present invention found that the aforementioned problem of the spontaneous polarization not oriented in a fixed direction could be resolved by a piezoelectric porcelain composition primarily constituted by such elements as Li, Na, K, Nb, Ta, Sb and O and having an AN-PV structure, wherein such piezoelectric porcelain composition has an ABO₃ type perovskite structure as the unit lattice of Z=1 and also has a transition point at which the crystal structure changes from the monoclinic system to the tetragonal system.

The inventors also found an orientation associated with lower temperature dependence of piezoelectric characteristics than when the polarization orientation is not considered, where such orientation can be achieved by controlling the crystal system of the aforementioned piezoelectric porcelain composition at the time of polarization to control the orientation in which polarization occurs, thereby maintaining a fixed polarization orientation at all times even though the crystal-structure transition point exists between −50° C. and 150° C.

Furthermore, the inventors found that, with the aforementioned piezoelectric porcelain composition, expressed piezoelectric characteristics can be dramatically enhanced by controlling the crystal system at the time of polarization and thereby controlling the orientation in which polarization occurs.

The present invention was completed based on the problems and findings mentioned above, and the present invention provides the following:

[1] A piezoelectric porcelain composition primarily constituted by such elements as Li, Na, K, Nb, Ta, Sb and O and having an AN-PV structure, wherein such piezoelectric porcelain composition is characterized in that when it has an ABO₃ type perovskite structure as the unit lattice of Z=1, it has a transition point at which the crystal structure changes from the monoclinic system to the tetragonal system.

[2] A piezoelectric porcelain composition according to [1] above, characterized in that, when the piezoelectric porcelain composition has an ABO₃ type perovskite structure as the unit lattice of Z=1, it has a transition point at which the crystal structure changes from the monoclinic system defined by space group Pm to the tetragonal system defined by space group P4 mm.

[3] A piezoelectric porcelain composition according to [2] above, expressed by the general formula {Liₓ[Na_{1-y}K_{y}]₁₋ₓ}ᵢ{Nb_{1-z-w}Ta_{z}Sb_{w}}ⱼO₃ (wherein, in the formula, 0.03≦x<0.1, 0.3<y<0.7, 0.0≦z<0.3, 0≦w≦0.10, 0.95≦i≦1.01 and 0.95≦j≦1.01).

[4] A piezoelectric porcelain composition according to [3] above, characterized in that, when the X-ray diffraction line intensities I (h00), I (0k0) and I (001) relating to the surface indexes h00, 0k0 and 001 belonging to the crystal orientations <100>, <010> and <001> at crystal axis lengths of c>a>b where one of their inter-axis angles β satisfies β>90° are measured in a condition where the electric field applied at the time of the polarization process is vertical to the diffraction surface of the piezoelectric porcelain composition meeting Bragg's law, the line intensity ratios I (h00)/I (0k0) and I (001)/I (0k0) of the X-ray diffraction of the piezoelectric porcelain composition after the polarization process meet the following, provided that h=k=1=m (m is an integer of 1 or greater):

[I(h00)/I(0k0)]/[I₀(h00)/I₀(0k0)]<1

[I(001)/I(0k0)]/[I₀(001)/I₀(0k0)]>1

(in the formulas, J₀ (h00), J₀ (0k0) and J₀ (001) represent X-ray diffraction line intensities relating to the surface indexes h00, 0k0 and 001 in a non-polarized state, and must be measured by the same method used to measure I (h00), I (0k0) and I (001)).

[5] A piezoelectric porcelain composition according to [3] above, characterized in that, when the X-ray diffraction line intensities I (h00), I (0k0) and I (001) relating to the surface indexes h00, 0k0 and 001 belonging to the crystal orientations <100>, <010> and <001> at crystal axis lengths of c>a>b where one of their inter-axis angles β satisfies β>90° are measured in a condition where the electric field applied at the time of polarization process is vertical to the diffraction surface of the piezoelectric porcelain composition meeting Bragg's law, the line intensity ratios I (h00)/I (0k0) and I (001)/I (0k0) of the X-ray diffraction of the piezoelectric porcelain composition after the polarization process meet the following, provided that h=k=1=m (m is an integer of 1 or greater):

[I(h00)/I(0k0)]/[I₀(h00)/I₀(0k0)]>1

[I(001)/I(0k0)]/[I₀(001)/I₀(0k0)]>1

(in the formulas, I₀ (h00), I₀ (0k0) and I₀ (001) represent X-ray diffraction line intensities relating to the surface indexes h00, 0k0 and 001 in a non-polarized state, and must be measured by the same method used to measure I (h00), I (0k0) and I (001)).

[6] A piezoelectric ceramic component whose first electrode and second electrode are opposing each other via a piezoelectric ceramic layer, wherein such piezoelectric ceramic component is characterized in that the aforementioned piezoelectric ceramic layer is formed by a piezoelectric porcelain composition according to any one of [1] to [5] above.

[7] A piezoelectric ceramic component having multiple layers of first electrodes and second electrodes that are alternately layered via a piezoelectric ceramic layer in between and also having a first terminal electrode electrically connected to the aforementioned first electrodes and second terminal electrode electrically connected to the aforementioned second electrodes, wherein such piezoelectric ceramic component is characterized in that the aforementioned piezoelectric ceramic layer is formed by a piezoelectric porcelain composition according to any one of [1] to [5] above.

[8] A piezoelectric ceramic component having a board with a piezoelectric ceramic layer and also having a first electrode and second electrode positioned on top of the piezoelectric ceramic layer in an opposing manner, wherein such piezoelectric ceramic component is characterized in that the aforementioned piezoelectric ceramic layer is formed by a piezoelectric porcelain composition according to any one of [1] to [5] above.

[9] A piezoelectric ceramic component having multiple layers of first electrodes and second electrodes that are alternately layered on a board with a piezoelectric ceramic layer and also having a first terminal electrode electrically connected to the aforementioned first electrodes and second terminal electrode electrically connected to the aforementioned second electrodes, wherein such piezoelectric ceramic component is characterized in that the aforementioned piezoelectric ceramic layer is formed by a piezoelectric porcelain composition according to any one of [1] to [5] above.

[10] A process for producing a piezoelectric ceramic component characterized by comprising the step in which electrodes are formed on a piezoelectric ceramic layer which in turn is formed by a piezoelectric porcelain composition according to any one of [1] to [5] above, and which can have an AN-PV structure being a monoclinic perovskite structure, after which an electric field is applied to perform polarization.

### Effects of the Invention

A piezoelectric porcelain composition primarily constituted by such elements as Li, Na, K, Nb, Ta, Sb and O and having an AN-PV structure, as proposed by the present invention, has a transition point at which the crystal structure changes from the monoclinic system to the tetragonal system when the composition has an ABO₃ type perovskite structure as the unit lattice of Z=1. Accordingly, while the composition has its crystal-structure transition point between −50° C. and 150° C. in order to utilize the high piezoelectric effect at the MPB at the crystal-structure transition point, it also maintains ΔC>0 at all times. This means that, by embodying such piezoelectric porcelain composition having an AN-PV structure and the transition point at which the crystal structure changes from the orthorhombic system mentioned above to the tetragonal system, a piezoelectric porcelain composition, piezoelectric ceramic component or piezoelectric device associated with less sudden capacitance change can be provided, which can ultimately substitute a lead-based piezoelectric device that uses PbO having high environmental burdens.

Also, a piezoelectric porcelain composition according to the present invention can have two polarization orientations of <100> and <001>, and by intentionally performing a polarization process only in the polarization orientation of <001>, temperature dependence of piezoelectric characteristics at −50° C. to 150° C. can be reduced compared to when the present invention is not considered. For this reason, a piezoelectric porcelain composition that utilizes the MPB and has an AN-PV structure can be used to provide a lead-free piezoelectric porcelain composition usable as a piezoelectric ceramic component or piezoelectric device whose operation must be guaranteed over a wide temperature range of −50° C. to 150° C.

Furthermore, because it can take two polarization orientations of <100> and <001>, a piezoelectric porcelain composition according to the present invention can have a high electromechanical coupling constant. This is an effect not heretofore possible with conventional piezoelectric porcelain compositions based on the orthorhombic system or the tetragonal system.

### BRIEF DESCRIPTION OF THE DRAWINGS

FIG. 1 (a) is a drawing showing the crystal structure of a unit lattice based on an ABO₃ type perovskite structure where Z=1, while (b) illustrates the relationships of the lattice constants a, b, c, α, β and γ of the ABO₃ type perovskite structure.

FIG. 2 A drawing showing the relationships of the lattice constants a, b, c, α, β and γ of a tetragonal crystal structure where Z=1 and P4 mm is symmetrical.

FIG. 3 A drawing showing the relationships of the lattice constants a, b, c, α, β and γ of an orthorhombic crystal structure where Z=2 and Amm2 is symmetrical.

FIG. 4 A drawing showing the relationships of the lattice constants a, b, c, α, β and γ of a monoclinic crystal structure where Z=1 and Pm is symmetrical.

FIG. 5 A side view showing an example of a piezoelectric ceramic component according to the present invention.

FIG. 6 A schematic section view showing an example of a piezoelectric ceramic component according to the present invention.

FIG. 7 A plan view showing an example of a piezoelectric ceramic component according to the present invention.

FIG. 8 A schematic section view showing an example of a piezoelectric ceramic component according to the present invention.

FIG. 9 A graph showing X-ray diffraction profiles of a conventional piezoelectric porcelain composition, measured at the temperatures shown in the graph.

FIG. 10 A graph showing X-ray diffraction profiles of a piezoelectric porcelain composition according to the present invention, measured at the temperatures shown in the graph.

FIG. 11 A graph showing X-ray diffraction profiles measured on a piezoelectric porcelain composition according to the present invention, as fitted by the Rietveld method.

FIG. 12 A bright field STEM image of a piezoelectric porcelain composition according to the present invention.

FIG. 13 A photograph showing the CBED pattern of zone axis [10 1 4] taken from a piezoelectric porcelain composition according to the present invention.

FIG. 14 A graph showing the temperature characteristics of the capacitance before polarization process (Cb) and capacitance after polarization process (Ca) of a piezoelectric porcelain composition according to the present invention.

FIG. 15 A graph showing the temperature characteristics of the capacitance before polarization process (Cb) and capacitance after polarization process (Ca) of a conventional piezoelectric porcelain composition.

FIG. 16 A graph showing the result of comparison of the rates of change in capacitance before and after polarization (ΔC) of a piezoelectric porcelain composition according to the present invention (No. 1-7) and conventional piezoelectric porcelain composition (No. 1-16).

FIG. 17 A graph showing the measured results of electromechanical coupling constant kp in the surface expansion direction of a disk-shaped vibrator, calculated for Sample No. #2-7 (a) and Sample No. 2-6 (b).

FIG. 18 A graph showing the measured results of diffraction intensity on the reflective surface of a sample in a non-polarized state, obtained using the X-ray diffraction method.

FIG. 19 A graph showing the measured results of diffraction intensity on the reflective surface of a monoclinic sample after polarization process (No. 2-6), obtained using the X-ray diffraction method.

FIG. 20 A graph showing the measured results of diffraction intensity on the reflective surface of a tetragonal sample after polarization process (No. #2-7), obtained using the X-ray diffraction method.

FIG. 21 Enlarged views of 200, 020 and 002 diffraction lines of a monoclinic perovskite structure present in the range of 44°≦2θ≦47° of an X-ray diffraction profile measured at −25° C.

FIG. 22 Enlarged views of 200, 020 and 002 diffraction lines of a monoclinic perovskite structure present in the range of 44°≦2θ≦47° of an X-ray diffraction profile measured at 25° C.

FIG. 23 Enlarged views of 200 and 002 diffraction lines of a tetragonal perovskite structure present in the range of 44°≦2θ≦47° of an X-ray diffraction profile measured at 125° C.

### DESCRIPTION OF THE SYMBOLS

101: Piezoelectric ceramic layer
102: First electrode
103: Second electrode
104: First terminal electrode
   105: Second terminal electrode
   106: Board
   107: Elastic body
   108: Contact

### Mode for Carrying Out the Invention

The present invention proposes a piezoelectric porcelain composition primarily constituted by such elements as Li, Na, K, Nb, Ta, Sb and O and having an AN-PV structure, wherein such piezoelectric porcelain composition has a transition point at which the crystal structure changes from the monoclinic system to the tetragonal system when it has an ABO₃ type perovskite structure as the unit lattice.

If an ABO₃ type perovskite structure is taken on as the unit lattice of Z=1, the orientation of spontaneous polarization after the polarization can be fixed when the crystal structure changes from the monoclinic system to the tetragonal system, unlike when the crystal structure changes from the orthorhombic system or monoclinic system with a molecular number of 2 or greater (Z≧2) to the tetragonal system as mentioned above, which means that sudden change in capacitance can be reduced even when the crystal-structure transition point exists between −50° C. and 150° C. Also because the orientation of spontaneous polarization after the polarization can be fixed, temperature dependence of piezoelectric characteristics is stable, despite the transition of the crystal structure.

The orientation of spontaneous polarization as determined by the crystal structure is explained in greater detail below.

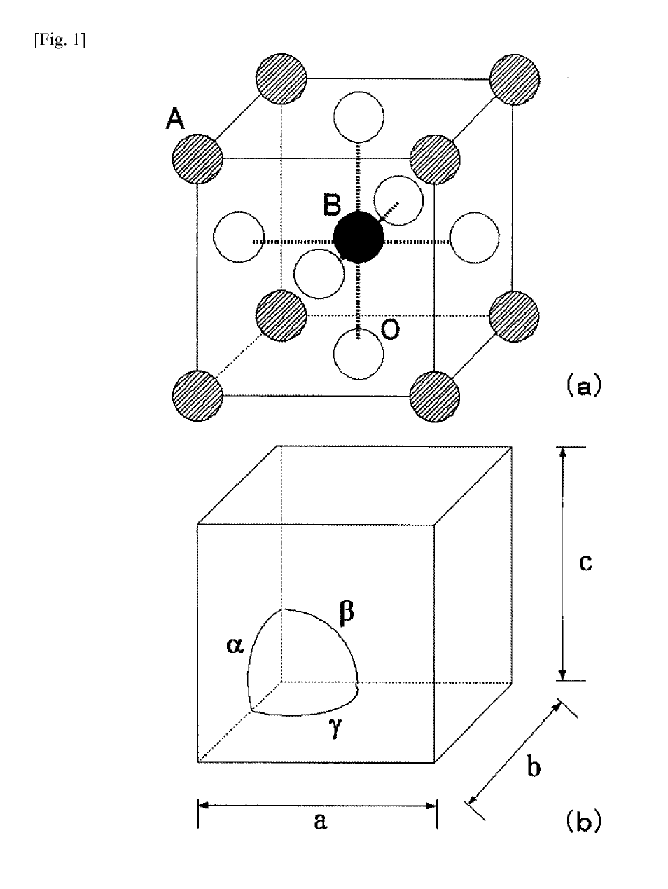

First, the definition of ABO₃ type perovskite structure pertaining to the present invention is explained. An ABO₃ type perovskite structure represents the crystal structure shown in FIG. 1(a), where six O's are positioned around the B site, while 12 O's are positioned around the A site. Also, angles between crystal axes are defined as shown in FIG. 1(b). These a, b, c, α, β and γ are called “lattice constants” and provide a general definition means in the field of crystallography.

Note that in the crystal structure shown in FIG. 1(a), the A site is positioned at a corner of the hexahedron and therefore only one atom exists inside the hexahedron, while the B site is positioned at the center of the hexahedron and therefore only one atom exists, and yet while the O site is positioned at the center of each side of the hexahedron and therefore a total of three atoms exist. Accordingly, the number of atoms indicated by ABO₃ exist in the hexahedron shown in FIG. 1(a). This condition is defined as the unit lattice where the molecular number is 1 (Z=1).

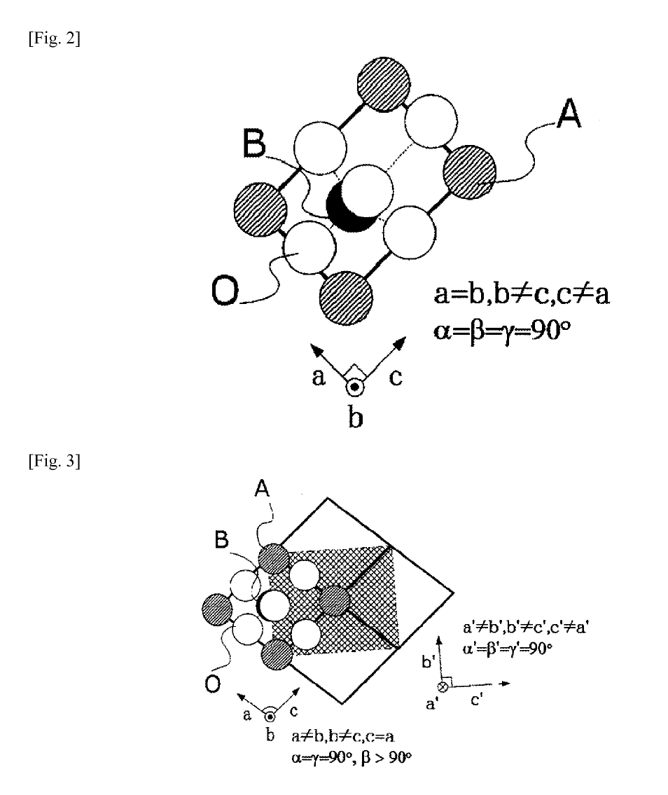

Now, with a piezoelectric porcelain composition having an AN-PV structure and the cyclical atom structure defined in FIG. 1, the tetragonal system means a crystal structure whose unit lattice illustrated by the schematic view in FIG. 2 has symmetry as defined by space group P4 mm (No. 99). Space groups are 230 types of crystallographically possible crystal symmetry as defined in International Table for Crystallography Volume A. In the case of this crystal structure defined by the tetragonal system, spontaneous polarization occurs in the orientation of c-axis, or orientation of [001], and thus the crystal structure can respond to an electric field applied externally. By applying a polarization process, the orientation of spontaneous polarization of the crystal structure can be aligned with the direction in which an electric field is applied, and after the piezoelectric porcelain composition has undergone the polarization process, the domain structure in each crystal constituting the multi-crystal structure of porcelain, is oriented in the direction in which the electric field is applied. Only then the piezoelectric porcelain composition exhibits piezoelectric effect. This means that, with a piezoelectric porcelain composition having an AN-PV structure based on the tetragonal system, the [001] orientation of the crystal structure aligns with the direction in which the electric field is applied at the time of polarization process.

Next, a schematic view of a crystal structure defined by the orthorhombic system is shown in FIG. 3. In this case, the crystal structure is defined by a molecular number of 2 (Z=2) and symmetry defined by space group Amm2 (No. 38), as shown in the shaded area in FIG. 3, where the lattice constants have the relationships of a′, b′, c′, α′, β′ and γ′ shown in FIG. 3. This crystal structure defined by the orthorhombic system undergoes spontaneous polarization in the orientation of c′-axis, or orientation of [001], and this orthorhombic system can be redefined by the relationships of lattice constants a, b, c, α, β and γ in FIG. 3 if it is assumed to have a unit lattice of Z=1. For the purpose of simplification, this redefined unit lattice of Z=1 is used in the following explanations. According to this definition, spontaneous polarization occurs in the orientation of [−101]. Compared to the schematic view of the tetragonal system in FIG. 2, clearly the orientation of spontaneous polarization is inclined in the unit lattice of Z=1.

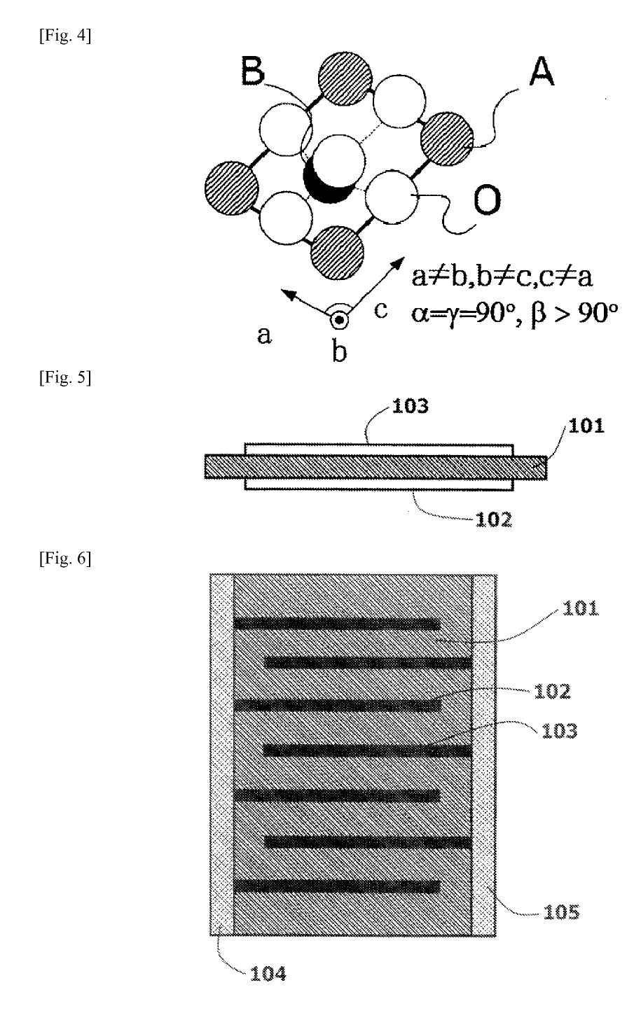

Next, a schematic view of a monoclinic crystal structure having an ABO₃ type perovskite structure as the unit lattice of Z=1 and symmetry of space group Pm (No. 6) is shown in FIG. 4. This crystal structure defined by the monoclinic system can undergo spontaneous polarization in the orientation of c-axis, or orientation of [001]. Also because the space group is Pm, the crystal system can have any orientation of spontaneous polarization within the plane of {010}. This means that, when the piezoelectric porcelain composition having an AN-PV structure has the aforementioned monoclinic crystal structure of Z=1 and has Pm symmetry, it can assume a condition in which the crystal structure is oriented in the orientation of [001] even after the polarization process. Also because the space group is Pm, naturally spontaneous polarization occurs in orientations other than c-axis. For example, spontaneous polarization in the orientations of [100] and [101], in addition to [001], is also possible.

As explained above, a cause of the problem of significant change in capacitance before and after the crystal-structure transition point is that the orientation of spontaneous polarization changes as the crystal structure changes. Accordingly, one possible way to avoid this phenomenon with the aforementioned piezoelectric porcelain composition having an AN-PV structure as well as a transition point at which the crystal structure changes from the orthorhombic system to the tetragonal system or from the monoclinic system of Z≧2 to the tetragonal system between −50° C. and 150° C., is to adjust the aforementioned crystal-structure transition point to outside the temperature range where the piezoelectric device operates. However, such method naturally contradicts the design of piezoelectric porcelain compositions having an AN-PV structure whose purpose is to embody high piezoelectric characteristics using the MPB at the crystal-structure transition point.

When the ABO₃ type perovskite structure is taken on as the unit lattice of Z=1 as proposed earlier, the orientation of spontaneous polarization can be fixed across the crystal-structure transition point as pointed out above, as long as the crystal structure changes from the monoclinic system defined by space group Pm to the tetragonal system defined by space group P4 mm at this transition point. To be specific, as long as a [001]-oriented polarized condition is maintained at all times among the orientations mentioned above, the capacitance rises after the polarization process with either crystal structure, and consequently the piezoelectric characteristics represented by the electromechanical coupling constant become stable, and this makes it possible to embody high piezoelectric characteristics at the MPB because the crystal-structure transition point exists in the operating temperature range (such as −50° C. to 150° C.) of the piezoelectric device, while reducing the sudden change in capacitance.

Furthermore, a piezoelectric porcelain composition according to the present invention, where the characteristics of the aforementioned monoclinic crystal structure of Z=1 and having Pm symmetry can be utilized and the polarization orientation of [101] is taken, can achieve a higher electromechanical coupling constant than when the polarization process is performed without considering the polarization orientation.

In addition, a piezoelectric porcelain composition according to the present invention is expressed by the composition formula {Liₓ[Na_{1-y}K_{y}]₁₋ₓ}ᵢ{Nb_{1-z-w}Ta_{z}Sb_{w}}ⱼO₃, wherein x, y, z, w, i and j in the composition formula are in the ranges of 0.03≦x<0.1, 0.3<y<0.7, 0.0≦z<0.3, 0.0≦w<0.1, 0.95≦i≦1.01 and 0.95≦j≦1.01, respectively. A piezoelectric porcelain composition expressed by such composition formula has an ABO₃ type perovskite structure and can have a transition point at which the crystal structure changes from the monoclinic system characterized by the unit lattice with a molecular number of 1 (Z=1) to the tetragonal system.

Also, with a piezoelectric porcelain composition according to the present invention, at least one type of first transition element from among Sc, Ti, V, Cr, Mn, Fe, Co, Ni and Zn can be mixed by a specified amount to control the sintering temperature and grain growth or extend the life when subjected to a high electric field, but these elements may or may not be used. Furthermore, with a piezoelectric porcelain composition according to the present invention, at least one type of second transition element from among Y, Zr, Mo, Ru, Rh, Pd and Ag can be mixed by a specified amount to control the sintering temperature and grain growth or extend the life when subjected to a high electric field, but these elements may or may not be used. Moreover, with a piezoelectric porcelain composition according to the present invention, at least one type of third transition element from among La, Ce, Pr, Nd, Sm, Eu, Gd, Tb, Dy, Ho, Er, Tm, Yb, Lu, Hf, W, Re, Os, Ir, Pt and Au can be mixed by a specified amount to control the sintering temperature and grain growth or extend the life when subjected to a high electric field, but these elements may or may not be used.

In addition, at least one type of first, second or third transition element from among the elements mentioned above can be mixed by a specified amount to control the sintering temperature and grain growth or extend the life when subjected to a high electric field, but similar effects can be achieved regardless of whether multiple elements are combined or not.

A piezoelectric porcelain composition according to the present invention has a perovskite structure generally indicated by ABO₃. Here, the element positioned at A is K, Na or Li, while the element positioned at B is Nb, Ta or Sb. Ideally when the stoichiometric ratio is A:B=1:1, all sites are completely filled with an element and a stable structure is achieved. As evident from the constituent elements of the composition, however, the composition eventually changes by several percent, or specifically 2% or less, due to elution of K, Na and Li due to moisture content, volatilization of K, Na, Li and Sb in the tentative sintering process, and volatilization of K, Na, Li and Sb in the sintering process, among others. These variations in constituent elements can occur when their material, timing of synthesis and synthesis process are changed.

Methods to address these variations include, for example, intentionally introducing slightly larger quantities of materials for K, Na, Li and Sb at the time of initial blending and bringing A:B closer to an ideal ratio of 1:1 after the final process, or specifically sintering process. To achieve a porcelain composition providing high piezoelectric effect, preferably the final ratio of A site and B site should be adjusted to within a range of 0.98<A/B<1.01. Such intentional adjustment of element quantities at the time of initial blending is a general method used in the synthesis of almost all porcelain compositions. Furthermore, adjusting the aforementioned ratio to within a range 0.95<A/B≦0.98 can improve the sintering property, but such method is already known when it comes to piezoelectric porcelain compositions having an AN-PV structure.

Next, a piezoelectric ceramic component using a piezoelectric porcelain composition according to the present invention is explained using FIGS. 5 to 8.

The piezoelectric ceramic component shown in the side view of FIG. 5 has a first electrode 102 and second electrode 103 opposing each other via a plate-like piezoelectric ceramic layer 101. This piezoelectric ceramic component can be obtained in the following way, for example. A material powder mix of piezoelectric porcelain composition is mixed with a binder, and the mixture is formed into the shape of a rectangle, rough circle or ring and then sintered to form a plate-like piezoelectric ceramic layer. A conductive paste using a conductive material such as Cu, Ag, Au, Pt, etc., is coated on both sides of the piezoelectric ceramic layer and the coated layer is baked to obtain the piezoelectric ceramic component shown in FIG. 5. By using a piezoelectric porcelain composition according to the present invention for the piezoelectric ceramic layer of this piezoelectric ceramic component, sudden change in capacitance at the crystal-structure transition point can be suppressed while exhibiting high piezoelectric effect at the MPB. This means that, when the present invention is applied to a sensor such as a pressure sensor, impact sensor or the like, a practical sensor offering higher sensitivity and producing less characteristic change due to temperature can be obtained.

The piezoelectric ceramic component shown in the schematic section view of FIG. 6 has multiple layers of first electrodes 102 and second electrodes 103 that are layered alternately via a piezoelectric ceramic layer 101 in between, wherein such piezoelectric ceramic component has a first terminal electrode 104 electrically connected to the first electrodes and second terminal electrode 105 electrically connected to the second electrodes, and this stacked piezoelectric ceramic component is used for stacked piezoelectric actuators, etc. By using a piezoelectric porcelain composition according to the present invention for this piezoelectric ceramic layer, sudden change in capacitance at the crystal-structure transition point can be suppressed while exhibiting high piezoelectric effect at the MPB. This means that, when the present invention is applied to a stacked actuator, etc., sudden change in response can be prevented, even across the crystal-structure transition point, because response depends on capacitance.

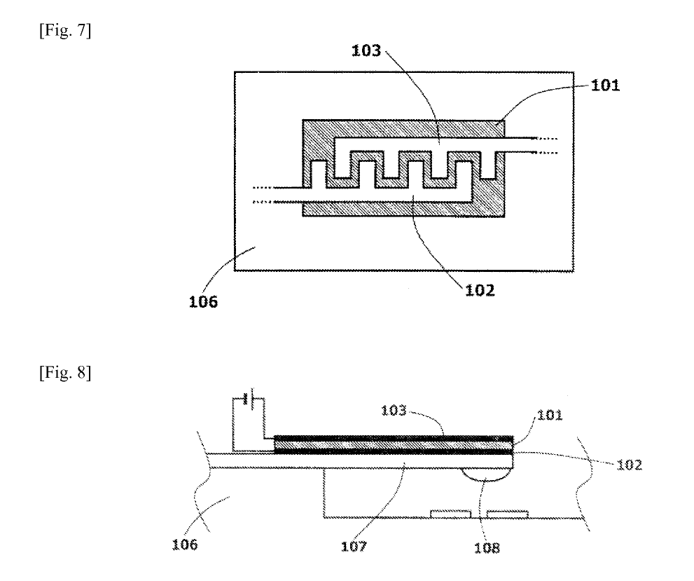

The piezoelectric ceramic component shown in the plan view of FIG. 7 has a piezoelectric ceramic layer 101 formed on a board 106, wherein such piezoelectric ceramic component has a first electrode 102 and second electrode 103 opposing each other in a manner roughly flush with the piezoelectric ceramic layer on the board, and in this example the piezoelectric device using such piezoelectric ceramic component is a piezoelectric surface acoustic wave filter (SAW filter). By using a piezoelectric porcelain composition according to the present invention for this piezoelectric ceramic layer, a SAW filter associated with easy circuit design and high productivity can be obtained, for example.

The piezoelectric ceramic component shown in the schematic section view of FIG. 8 has a first electrode 102 and second electrode 103 positioned on a board 106 in a manner opposing each other via a piezoelectric ceramic layer 101, and in this example the piezoelectric device using such piezoelectric ceramic component is a switch element using a flex-type piezoelectric actuator. In the figure, reference numeral 107 indicates an elastic body, while reference numeral 108 indicates a contact. By using a piezoelectric porcelain composition according to the present invention for this piezoelectric ceramic layer, sudden change in response can be prevented, even across the crystal-structure transition point, because response depends on capacitance, as is the case with the stacked actuator, etc., mentioned above. Note that, while FIG. 8 shows a uni-morph piezoelectric actuator having one piezoelectric ceramic layer, it can also be a bi-morph or multi-morph piezoelectric actuator having two or more piezoelectric ceramic layers.

The specific means are explained specifically below in order to reveal the aforementioned details pertaining to the present invention.

First, the following procedure was followed to obtain a piezoelectric porcelain composition having an AN-PV structure, as mentioned in the present invention, regardless of whether or not such piezoelectric porcelain composition was included in the scope of claims under the present invention. As the starting materials, Li₂CO₃, Na₂CO₃ (or NaHCO₃), K₂CO₃ (or KHCO₃), Nb₂O₅, Ta₂O₅, Sb₂O₃ (or SB₂O₅) having a purity of 99% or higher were prepared and these materials were weighed in such way as to obtain a piezoelectric porcelain composition within the range expressed by the composition formula {Liₓ[Na_{1-y}K_{y}]₁₋ₓ}ᵢ{Nb_{1-z-w}Ta_{z}Sb_{w}}ⱼO₃, after which the materials were mixed in a wet condition for approx. 24 hours using a ball mill, to obtain a mixture. Here, for the starting material Li₂CO₃, a commercially available Li₂CO₃ product was used after it was pre-crushed for 24 hours using a ball mill to adjust the average grain size to 1 μm or less. According to our study, generally commercially available Li₂CO₃ products have an average grain size of 5 or more and if any such Li₂CO₃ product is used, it is difficult to obtain a piezoelectric porcelain composition according to the present invention. Next, the aforementioned mixture was dried in atmosphere at approx. 100° C., and then calcined at 700° C. to 1000° C. to obtain a calcined powder. Thereafter, the powder was crushed in a wet condition for approx. 24 hours using a ball mill, and then dried in atmosphere at approx. 100° C. to obtain a crushed powder. This crushed powder was mixed with an organic binder and the mixture was passed through a 60-mesh sift to adjust the granularity, after which the powder was put through single-axial forming under a pressure of 1000 kg/cm² to be formed into a disk of 10 mm in diameter and 0.5 mm in thickness, and the disk was sintered in atmosphere at 950° C. to 1200° C. to obtain a disk-like piezoelectric porcelain composition.

A silver paste was coated on both surfaces of the aforementioned piezoelectric porcelain composition and the composition was baked at 850° C. to form silver electrodes and thereby obtain a piezoelectric porcelain composition sample before polarization, after which an electric field of approx. 3 to 4 kV/mm equal to or greater than the coercive electric field in insulating oil was applied in the form of DC voltage to perform a polarization process for 15 minutes, and then the polarized composition was left stationary overnight to obtain a piezoelectric porcelain composition sample after polarization.

The aforementioned polarization process generally refers to a process of applying a strong electric field equal to or greater than the coercive electric field to the piezoelectric porcelain composition and thereby aligning the domain orientations compared to a non-polarized state, and this process is always necessary in order to express piezoelectric effect.

The coercive electric field refers to an electric field intensity at which the domain orientation in each crystal constituting a multi-crystal structure does not change unless a greater electric field is applied. In general, an electric field in a range of several hundreds of V/mm to several thousands of V/mm must be applied.

A non-polarized state refers to a state where no electric field is applied to the piezoelectric porcelain composition or the applied electric field is lower than the coercive electric field and each crystal constituting the multi-crystal structure of the piezoelectric porcelain composition has a random domain orientation.

Even if the piezoelectric porcelain composition has undergone a polarization process, the polarization process will be undone and the composition will return to a non-polarized state if the crystals having a perovskite structure that constitute the multi-crystal structure of the piezoelectric porcelain composition are heated to at least the temperature at which the crystal structure changes to the tetragonal system. The aforementioned temperature is generally referred to as the “curie temperature.” This is because, with the tetragonal system, the domain in the crystal will disappear at this temperature due to symmetry of its crystal structure.

Note that, after the piezoelectric porcelain composition that had undergone a polarization process is heated to the curie temperature or above and the composition returns to a non-polarized state, the composition can still be returned to a polarized state by applying a strong electric field equal to or greater than the coercive electric field at the curie temperature or below.

Once the piezoelectric porcelain composition undergoes a polarization process, the domain structure in each crystal constituting the multi-crystal structure of porcelain is oriented in the direction in which the electric field has been applied. Only then does the piezoelectric porcelain composition exhibit piezoelectric effect.

Also, because the polarization orientation varies depending on the crystal system assumed by the piezoelectric porcelain composition at the time of the polarization process, it is possible to design desired temperature dependence of piezoelectric characteristics or obtain a high electromechanical coupling constant, as described in “Effects of the Invention,” by evaluating the crystal system and performing the polarization process accordingly. Specifically, the crystal system can be controlled with ease by setting insulating oil to a specified temperature at the time of polarization or applying pressure to the piezoelectric porcelain composition.

By following the above procedure, it is possible to obtain a piezoelectric porcelain composition having an AN-PV structure as mentioned under the present invention, or piezoelectric porcelain composition having an AN-PV structure whose polarization orientation has been controlled.

Next, the piezoelectric porcelain composition having an AN-PV structure as obtained by the aforementioned procedure was crushed for approx. 30 minutes in an agate mortar after stripping off the silver electrodes, and then X-ray diffraction profiles were measured at temperatures before and after the crystal-structure transition point, in order to evaluate whether or not a piezoelectric porcelain composition as expected under the present invention was achieved and also to measure how the crystal structure would change, especially before and after the crystal-structure transition point. The RINT-2500PC based on parallel beam optics (manufactured by Rigaku, headquartered at 3-9-12 Matsubara-cho, Akishima-shi, Tokyo) was used as the X-ray diffractometer, Cu—Kα ray was used as the characteristic X ray, and the voltage and current applied to generate the characteristic X ray were set to 50 kV and 300 mA, respectively. The 2θ/θ method was used as the measurement method, and measurement was performed every four seconds at 0.02° intervals using the fixed time method. Then, a diffraction profile was obtained over a range of 44°≦2θ≦47°, and the obtained diffraction profile was used to evaluate whether a monoclinic crystal structure of Z=1 exists on the lower-temperature side of the crystal-structure transition point, in order to check whether or not a piezoelectric porcelain composition within the scope of the present invention was obtained.

Additionally after checking the change in the crystal system at the crystal-structure transition point, an X-ray diffraction profile was measured at 25° C. on the piezoelectric porcelain composition exhibiting a monoclinic crystal structure of Z=1 around room temperature (25° C.) and lattice constants were calculated from the obtained X-ray diffraction profile using the Rietveld method, in order to determine the crystal structure more accurately.

The Rietveld method provides an effective means to calculate lattice constants in X-ray diffraction of powder, determine the atom positioned at each site of the crystal structure, and specify the positions of atoms in the structure, and is used generally not only in the field of piezoelectric ceramics, but also in many fields of functional ceramics.

The analysis by the Rietveld method was conducted using the tetragonal crystal structure model of Z=1 and having symmetry of P4 mm, the orthorhombic crystal structure model of Z=2 having symmetry of Amm2, and the monoclinic crystal structure model of Z=1 and having symmetry of Pm, as mentioned above, and an optimal crystal structure model was specified from among the aforementioned crystal structure models. Also, the occupancy ratio of the atom positioned at each site of the crystal structure, atom coordinates, temperature factors and other parameters required under the Rietveld method were analyzed using ranges of values that are generally taken in the case of an ABO₃ type perovskite structure. Additionally, for measurement of X-ray diffraction profile at 25° C., the RINT-2500PC based on focused optics was used as the X-ray diffractometer, CU—Kα ray was used as the characteristic X-ray, and voltage and current applied to generate the characteristic X-ray were set to 50 kV and 100 mA, respectively. The 2θ/θ method was used as the measurement method, and measurement was performed every second at 0.02° intervals using the fixed time method over a measurement range of 20°≦2θ≦90°. The measurement sample was prepared by stripping the piezoelectric porcelain composition of its silver electrodes and then crushing the composition for around 30 minutes in an agate mortar.

Then, by specifying the optimal crystal structure model as obtained from the above method, and based on the calculated results of lattice constants, presence of the aforementioned monoclinic crystal model of Z=1 and having symmetry of Pm was verified.

Furthermore, to verify whether the aforementioned crystal structure model would be feasible and the aforementioned changes in lattice constants were appropriate from minute viewpoints, within the crystals constituting the multi-crystal structure of the piezoelectric porcelain composition completing the verification of presence of the monoclinic crystal model of Z=1 and having symmetry of Pm using the aforementioned Rietveld method, a sample was created from a thin section of each piezoelectric porcelain composition and observed by a transmission electron microscope (TEM) to obtain an electron beam diffraction pattern at room temperature, along with a CBED (convergent-beam electron diffraction) pattern from higher-order crystal axes, and HOLZ (higher-order Laue zone) lines appearing on these patterns were analyzed to evaluate the space groups and lattice constants of the crystal structure. Note that, in obtaining the CBED pattern, the applied electron beam voltage was 200 keV and outside air temperature of the measurement chamber was set to 25° C.

Examples of this evaluation method include those described in Patent Literature 6 and Non-patent Literature 7. Also, Non-patent Literature 8 presents an example of a material whose symmetry is relatively low, such as the orthorhombic perovskite used in the specific example provided herein, and based on these examples this method is generally used in the evaluation of lattice constants in the local areas of semiconductors, mono-crystal boards, piezoelectric ceramics, etc.
Patent Literature 6: Japanese Patent Laid-open No. 2007-71887
Non-patent Literature 7: Journal of Microscopy 194, Pt 1 (1999), 2-11
Non-patent Literature 8: Proceedings of the 21st Fall Meeting of the Ceramic Society of Japan, p. 300

As explained above, after a detailed check of presence of a monoclinic crystal structure of Z=1 on the lower-temperature side of the crystal-structure transition point, the X-ray diffraction method was used to check the diffraction intensities of key diffraction surfaces in order to observe the oriented state of the crystals constituting the multi-crystal structure of the piezoelectric porcelain composition resulting from the polarization process as mentioned above. Measurement was performed by polishing with a #2000 sandpaper and thereby stripping off the electrodes to expose the surfaces of the piezoelectric porcelain composition, and then orienting this piezoelectric porcelain composition sample in such a way that, when measurement was taken, the direction in which the electric field was applied at the time of polarization process would lie vertically to the diffraction surface of the piezoelectric porcelain composition meeting Bragg's law, after which a scan was performed based on the 2θ/θ method over a range of 44°≦2θ≦47°, while the total intensity was measured until sufficiency of measurement was confirmed. The rotary anticathode generator was used as the X-ray source, Cu—Kα ray was used as the characteristic X ray, and voltage and current applied to generate this characteristic X ray were set to 50 kV and 300 mA, respectively. A scintillation counter was used as the detector, while the RINT-2500PC based on parallel beam optics was used as the X-ray diffractometer.

Using the X-ray diffraction method to observe this state is a common method. This is because, by measuring the diffraction intensity of the diffraction surface indicated by the surface indexes h, k and 1, the oriented state can be observed.

The X-ray diffraction phenomenon occurs when Bragg's law as shown below is met by the position relationship of the diffracted X-ray and measured sample as a result of, for example, presence of a crystal lattice because the atoms constituting the subject substance of a mono-crystal or multi-crystal structure have a cyclical structural sequence:

2d sin θ=nλ Formula (0)

In Formula (0), d represents the width of the lattice surface pitch and corresponds to the diffraction surface pitch. θ indicates the incident angle and reflection angle (Bragg's angle) of the diffraction surface and X ray, and the diffraction phenomenon does not occur unless the incident angle and reflection angle are the same. n is an integer of 1 or greater, while λ is the wavelength of X ray.

In observing the state under the present invention using the X-ray diffraction method, a more preferred way is to control the generator position, position of the measured surface and detector position in such a way that the direction of the generator of incident X ray and direction of the detector that detects the reflected X ray would always form an equal angle relative to the measured surface, and measure Bragg's angle θ as a variable in this condition, so that the measured surface of the sample can be observed as the diffraction surface. This method is generally referred to as the “2θ/θ method.”

Also in observing the state under the present invention, use of X ray is a common method. However, electrons or neutrons can also be used as the light source, for example.

Additionally in observing the state under the present invention, preferably the x-ray source should be Cu—Kα ray (λ=1.5418 Å) which is the most common X-ray source. However, any other characteristic X ray can be used.

Furthermore, as the X-ray generator, a bulb type, rotary anticathode type, synchrotron type, cyclotron type and the like are available, and any type of X-ray generator can be used.

The same goes for the X-ray detector, where a scintillation counter, semiconductor detector and the like are available, and any type of detector can be used.

In measuring the line intensities I (h00), I (0k0), (001), etc., oftentimes the line intensity is not obtained accurately due to an overlap of diffraction lines, overlap of Kα1, Kα2, and so on. Accordingly, a more preferable way is to perform fitting on each diffraction line using the pseudo-Voigt function, etc., to separate any overlap of diffraction line or Kα1 and Kα2 before the evaluation. In the case of the present invention, line intensities were evaluated by eliminating the factors of overlap, etc., using the split pseudo-Voigt function (J. Appl. Cryst. (1990). 23, 485-491).

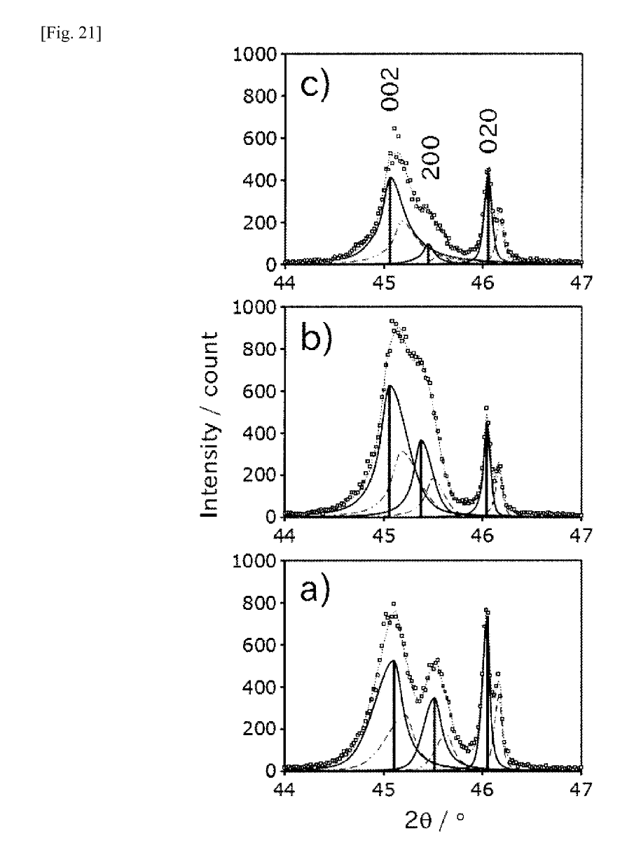

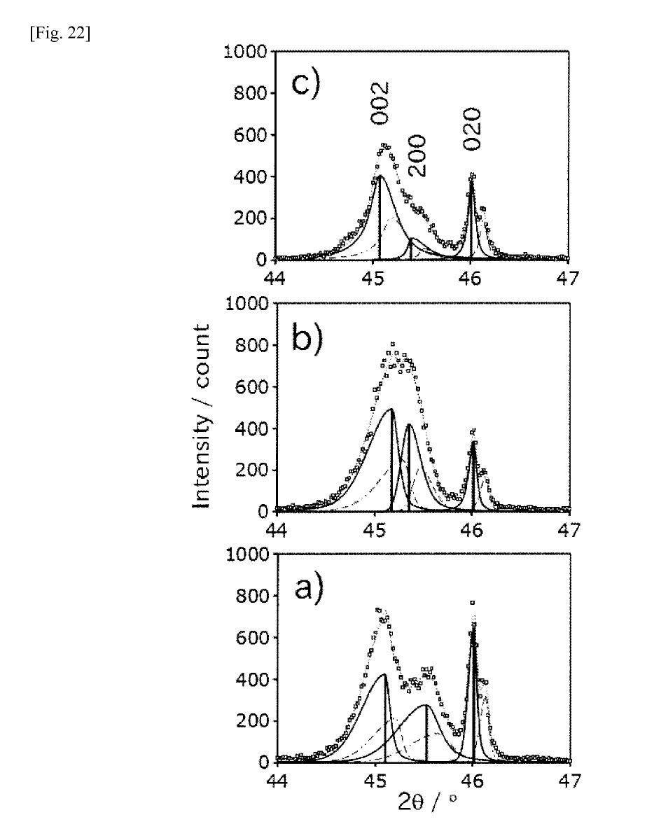

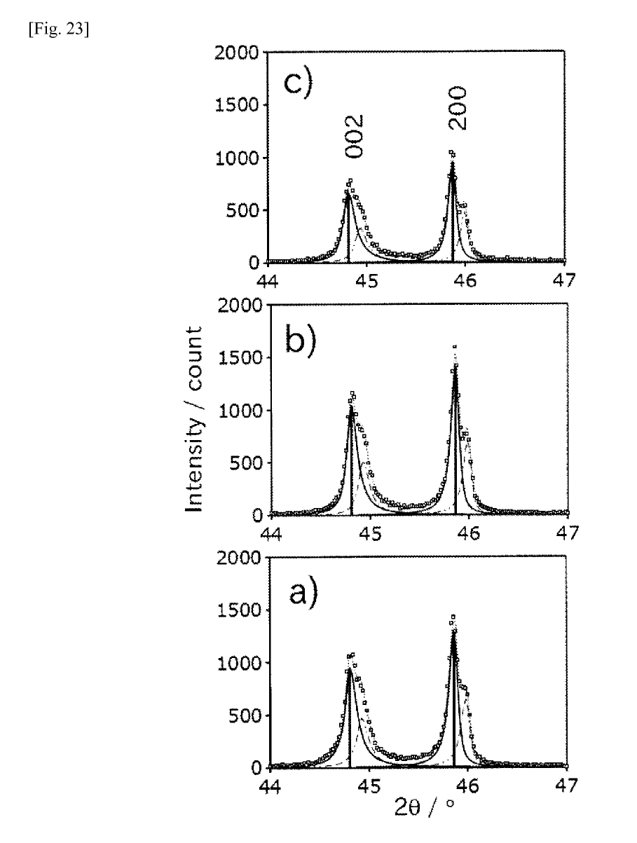

FIGS. 21 to 23, which are described later, show examples of fitting, where the plot, the two-dot chain line and the solid line represent the raw data, Kα2 and Kα1, respectively. Among these, the diffraction profile of Kα1 was evaluated as the line intensity.

Furthermore, to evaluate the temperature dependence of capacitance change before and after the polarization of the piezoelectric porcelain composition having an AN-PV structure, as obtained by the aforementioned procedure, the capacitance before polarization process (Cb) and capacitance after polarization process (Ca) of the piezoelectric porcelain composition were measured at measurement temperatures of −60° C. to 180° C. by holding each measurement temperature for 30 minutes until the temperature became steady. Measurement was performed according to the AC four-probe method using a LCR meter (E4980A manufactured by Agilent) at a measurement frequency of 1 kHz and measurement signal voltage of 1 Vrms.

Note that polarization to evaluate this temperature dependence of capacitance change was implemented at temperatures where the measured piezoelectric porcelain composition would take on the tetragonal system, in order to disregard any change in polarization orientation due to different crystal systems. The crystal system of the piezoelectric porcelain composition was determined based on the X-ray diffraction profile obtained in the temperature zone covering temperatures before and after the phase transition point as mentioned above.

To evaluate the piezoelectric characteristics of the piezoelectric porcelain composition having an AN-PV structure as obtained by the aforementioned procedure, the electromechanical coupling coefficient (kp) in the diameter direction of the disk was measured according to the resonance-antiresonance method using an impedance meter (HP4194A manufactured by Agilent). Measurements thus obtained were evaluated according to the EMAS-6100 standard of the Electronic Materials Manufacturers Association of Japan.

When the crystal system was determined and piezoelectric characteristics were evaluated using the methods mentioned above, the following became clear regarding the piezoelectric porcelain composition conforming to the present invention:

The piezoelectric porcelain composition conforming to the present invention, or specifically piezoelectric porcelain composition primarily constituted by such elements as Li, Na, K, Nb, Ta, Sb and O and having an AN-PV structure, was characterized by having a transition point at which the crystal structure changed from the monoclinic system to the tetragonal system when such composition had an ABO₃ type perovskite structure as the unit lattice of Z=1. Also, the monoclinic system had space group Pm, while the tetragonal system had space group P4 mm.

It was also found that the aforementioned characteristics would manifest when the constituent elements of the piezoelectric porcelain composition were within the ranges expressed by the composition formula {Liₓ[Na_{1-y}K_{y}]₁₋ₓ}ᵢ{Nb_{1-z-w}Ta_{z}Sb_{w}}ⱼO₃ (wherein, in the formula, 0.03≦x<0.1, 0.3<y<0.7, 0.0≦z<0.3, 0≦w≦0.10, 0.95≦i≦1.01 and 0.95j≦1.01).

In addition, with a piezoelectric porcelain composition characterized in that, when the X-ray diffraction line intensities I (h00), I (0k0) and I (001) relating to the surface indexes h00, 0k0 and 001 belonging to the crystal orientations <100>, <010> and <001> at crystal axis lengths of c>a>b where one of their inter-axis angles β satisfies β>90° at the monoclinic system are measured in a condition where the electric field applied at the time of polarization process is vertical to the diffraction surface of the piezoelectric porcelain composition meeting Bragg's law, the line intensity ratios I (h00)/I (0k0) and I (001)/I (0k0) of the X-ray diffraction of the piezoelectric porcelain composition after the polarization process meet the following, provided that h=k=1=m (m is an integer of 1 or greater):

[I(h00)/I(0k0)]/[I₀(h00)/I₀(0k0)]<1

[I(001)/I(0k0)]/[I₀(001)/I₀(0k0)]>1

(in the formulas, J₀ (h00), J₀ (0k0) and J₀ (001) represent X-ray diffraction line intensities relating to the surface indexes h00, 0k0 and 001 in a non-polarized state, and must be measured by the same method used to measure I (h00), I (0k0) and I (001)), temperature change of piezoelectric characteristics could be reduced from what was exhibited by the piezoelectric porcelain composition which was prepared in a straightforward manner without giving any consideration, such as the one expressed by the composition formula {Liₓ[Na_{1-y}K_{y}]₁₋ₓ}ᵢ{Nb_{1-z-w}Ta_{z}Sb_{w}}ⱼO₃, even when the MBP was present in a temperature zone of −50 to 150° C. Also, temperature change of an electromechanical coupling constant (such as kp) could be reduced further, and sufficient piezoelectric characteristics to replace lead could be achieved.

Additionally, with respect to the piezoelectric porcelain composition conforming to the present invention, with a piezoelectric porcelain composition characterized in that, when the X-ray diffraction line intensities I (h00), I (0k0) and I (001) relating to the surface indexes h00, 0k0 and 001 belonging to the crystal orientations <100>, <010> and <001> at crystal axis lengths of c>a>b where one of their inter-axis angles β satisfies β>90° are measured in a condition where the electric field applied at the time of polarization process is vertical to the diffraction surface of the piezoelectric porcelain composition meeting Bragg's law, the line intensity ratios I (h00)/I (0k0) and I (001)/I (0k0) of the X-ray diffraction of the piezoelectric porcelain composition after the polarization process meet the following, provided that h=k=1=m (m is an integer of 1 or greater):

[I(h00)/I(0k0)]/[I₀(h00)/I₀(0k0)]>1

[I(001)/I(0k0)]/[I₀(001)/I₀(0k0)]>1

(in the formulas, I₀ (h00), I₀ (0k0) and I₀ (001) represent X-ray diffraction line intensities relating to the surface indexes h00, 0k0 and 001 in a non-polarized state, and must be measured by the same method used to measure I (h00), I (0k0) and I (001)), an electromechanical coupling constant (such as kp) dramatically higher than what can be obtained from the piezoelectric porcelain composition which was prepared in a straightforward manner without giving any consideration, such as the one expressed by the composition formula {Liₓ[Na_{1-y}K_{y}]₁₋ₓ}ᵢ{Nb_{1-z-w}Ta_{z}Sb_{w}}ⱼO₃, could be achieved, and sufficient piezoelectric characteristics to replace lead could be achieved.

### EXAMPLES

The following reveals the novelty and inventiveness of the present invention using examples of piezoelectric porcelain compositions that were evaluated as deemed appropriate using the aforementioned means. Although the explanations are based on the examples, the present invention is not at all limited to these examples.

### Example 1

First, the composition formulas of piezoelectric porcelain composition samples having an AN-PV structure, produced according to the aforementioned procedure, are summarized in Table 1. Note that the samples denoted by * in the sample number field of Table 1 have a composition outside the scope of the present invention and are therefore considered comparative examples.

TABLE 1

| Sample No. | x | Y | z | w |
|---|---|---|---|---|
| *1-1 | 0.00 | 0.50 | 0.0 | 0.0 |
| *1-2 | 0.02 | 0.50 | 0.0 | 0.0 |
| 1-3 | 0.03 | 0.50 | 0.0 | 0.0 |
| 1-4 | 0.04 | 0.50 | 0.0 | 0.0 |
| 1-5 | 0.05 | 0.50 | 0.0 | 0.0 |
| 1-6 | 0.055 | 0.50 | 0.0 | 0.0 |
| 1-7 | 0.06 | 0.50 | 0.0 | 0.0 |
| 1-8 | 0.08 | 0.50 | 0.0 | 0.0 |
| *1-9 | 0.10 | 0.50 | 0.0 | 0.0 |
| 1-10 | 0.06 | 0.48 | 0.0 | 0.0 |
| 1-11 | 0.06 | 0.45 | 0.0 | 0.0 |
| 1-12 | 0.06 | 0.40 | 0.0 | 0.0 |
| *1-13 | 0.06 | 0.30 | 0.0 | 0.0 |
| 1-14 | 0.06 | 0.55 | 0.0 | 0.0 |
| 1-15 | 0.06 | 0.60 | 0.0 | 0.0 |
| *1-16 | 0.06 | 0.70 | 0.0 | 0.0 |
| 1-17 | 0.03 | 0.50 | 0.1 | 0.0 |
| 1-18 | 0.03 | 0.50 | 0.2 | 0.0 |
| 1-19 | 0.04 | 0.50 | 0.2 | 0.0 |
| *1-20 | 0.02 | 0.50 | 0.1 | 0.02 |
| 1-21 | 0.03 | 0.50 | 0.1 | 0.03 |
| 1-22 | 0.04 | 0.50 | 0.1 | 0.04 |
| 1-23 | 0.05 | 0.50 | 0.1 | 0.05 |

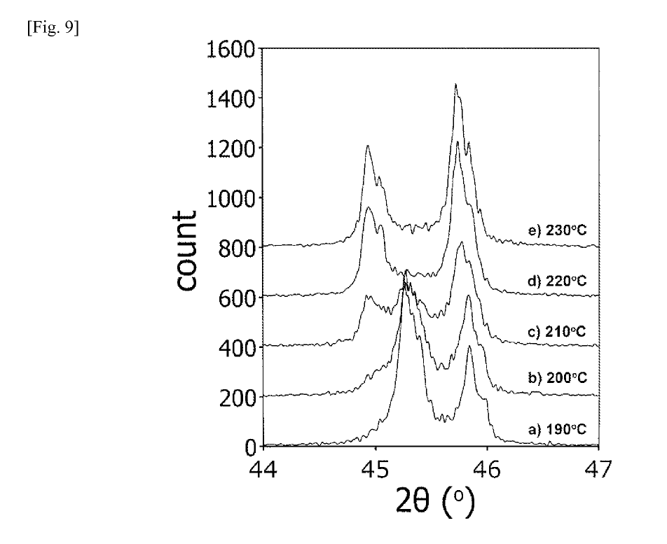

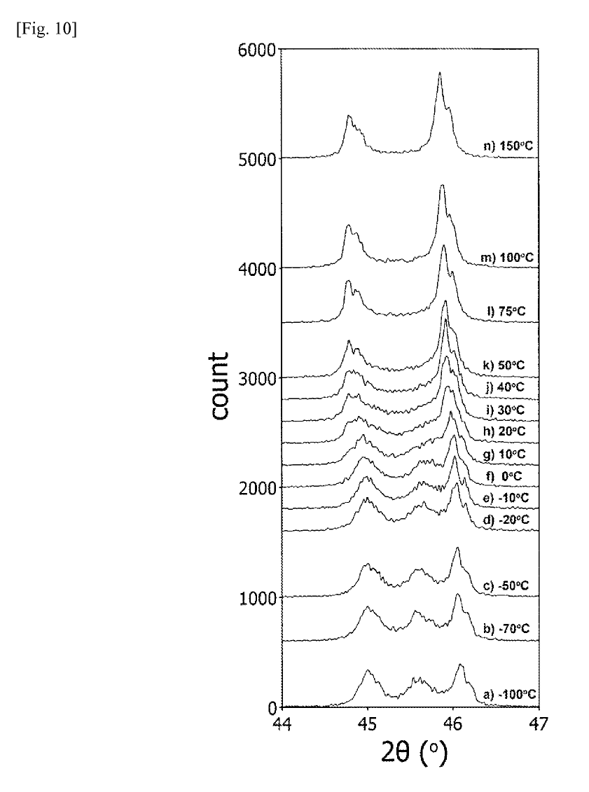

X-ray diffraction profiles of respective samples shown in Table 1 were measured at temperatures before and after the crystal-structure transition point using the aforementioned method, in order to evaluate in particular how the crystal structure would change before and after the transition point. FIG. 9 shows the diffraction profile of Sample No. 1-1 being a comparative example, while FIG. 10 shows the diffraction profile of Sample No. 1-7 conforming to the present invention, both measured in a range of 44°≦2θ≦47°. Also note that, by measuring how the X-ray diffraction profiles would change due to temperature as shown in FIGS. 9 and 10, presence or absence of a monoclinic crystal structure of Z=1 having symmetry of Pm was determined in a range of −50° C. to 150° C., with the results summarized in Table 4. In Table 4, the samples marked “Absent” did not have a transition point in a range of −50° C. to 150° C. at which the monoclinic crystal structure of Z=1 having symmetry of Pm as shown in FIG. 10 would change to the tetragonal crystal structure of Z=1 having symmetry of P4 mm. Also note that, in Table 4, the samples marked “Present” did have a transition point in a range of −50° C. to 150° C. at which the monoclinic crystal structure of Z=1 having symmetry of Pm as shown in FIG. 10 would change to the tetragonal crystal structure of Z=1 having symmetry of P4 mm.

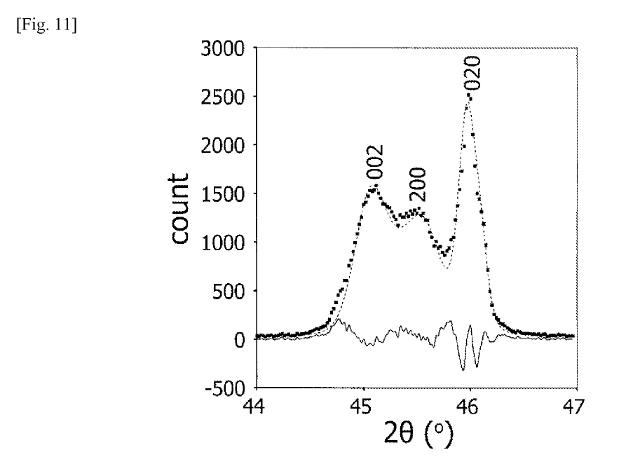

Also, samples that could take on the monoclinic crystal structure of Z=1 and having symmetry of Pm around room temperature (25° C.) were identified from the aforementioned measurement of temperature change of X-ray diffraction profiles, and X-ray diffraction profiles of the applicable samples, or Sample Nos. 1-5 to 1-7, were measured at 25° C., after which the obtained X-ray diffraction profiles were used to calculate the lattice constants according to the Rietveld method to study whether a monoclinic crystal structure of Z=1 and having symmetry of Pm could be identified, with the results shown in Table 2. In the table, a fitting error is shown in parentheses at the end of the value of each lattice constant. Also, the calculated values and measured values of fitting and their differences are shown in FIG. 11. In the graph, the plot, dotted line, and solid line indicate the measured XRD value, fitting result, and difference between the measured value and fitting value, respectively. The results in FIG. 11 confirm that sufficient fitting was achieved to support the aforementioned calculation of lattice constants according to the Rietveld method and determination of space groups and crystal systems.

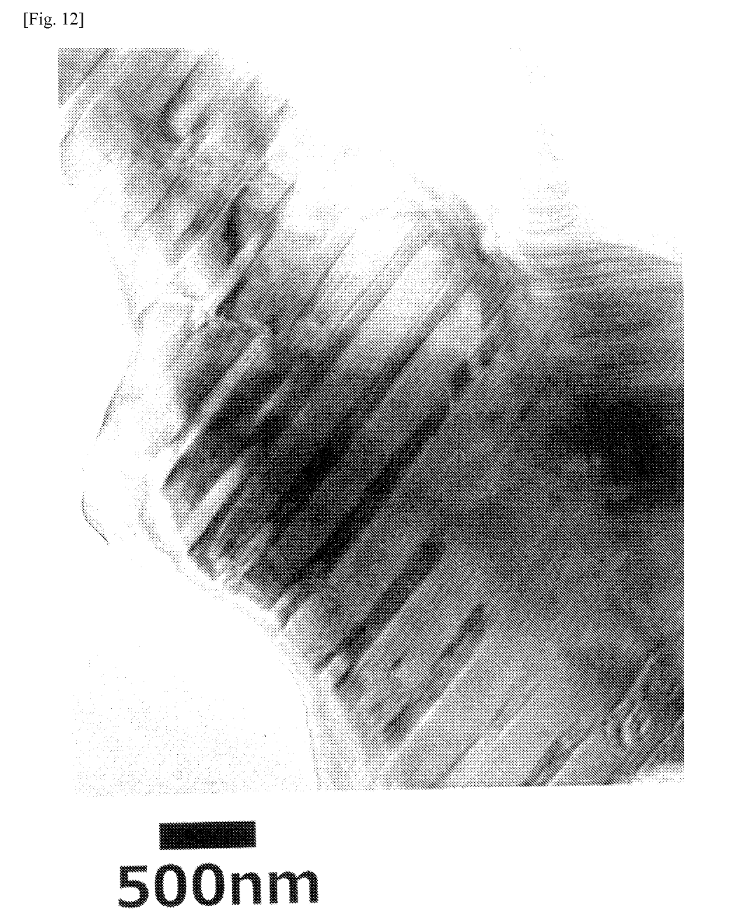

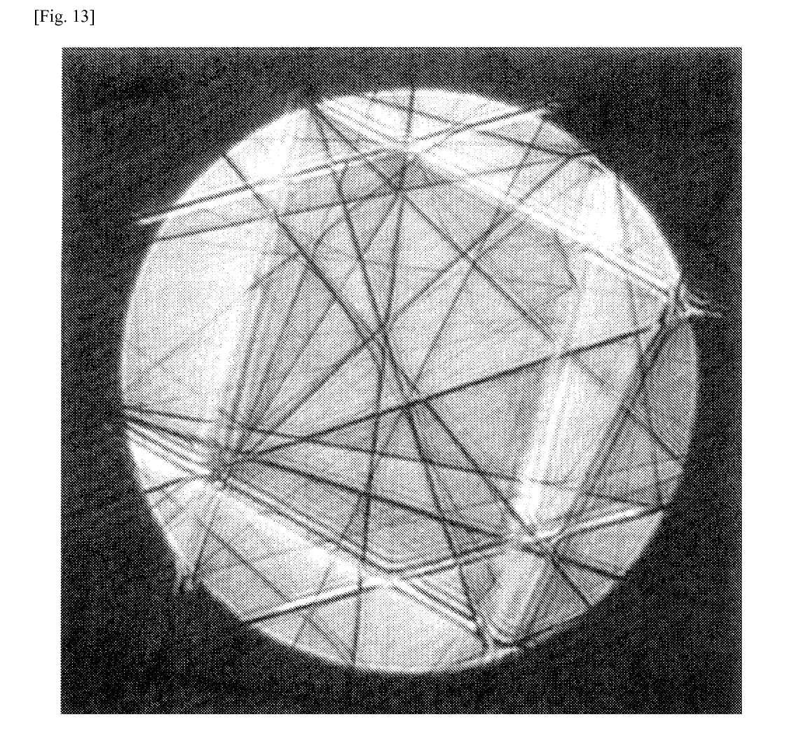

Additionally, for Sample Nos. 1-5 to 1-7, the aforementioned TEM was used to obtain an electron beam diffraction pattern at room temperature, along with a CBED pattern from higher-order crystal axes, and HOLZ lines appearing on these patterns were analyzed to evaluate the space groups and lattice constants of the crystal structure. A bright-field scanning transmission electron microscope (STEM) image of a thin section taken from Sample No. 1-6 is shown in FIG. 12 as an example. Evidently the crystal has a clear domain structure and is in a high crystalline state, suggesting that this sample is sufficient for evaluating the CBED pattern and HOLZ lines appearing on the pattern. Also, the CBED pattern obtained from a thin section taken from Sample No. 1-6, and HOLZ lines appearing on the pattern are shown in FIG. 13. By obtaining these images and then fitting the calculated values of distances between the intersecting points of HOLZ lines by the downhill simplex method, the lattice constants of a, b, c and β were calculated. The values were calculated using the monoclinic crystal structure model of Z=1 and having symmetry of Pm, with the results shown in Table 3. In the table, a fitting error is shown in parentheses at the end of the value of each lattice constant.

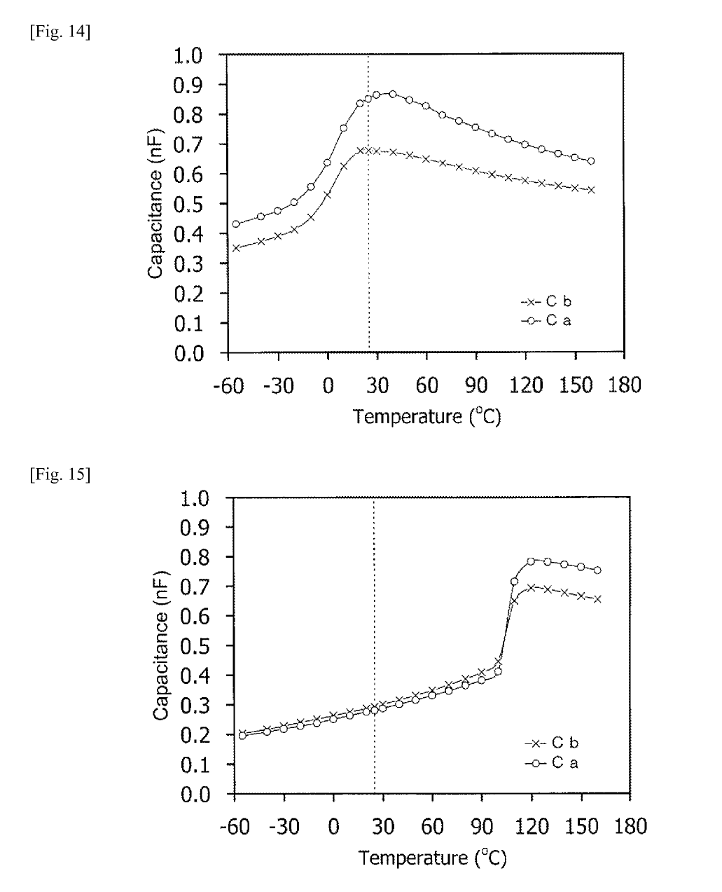

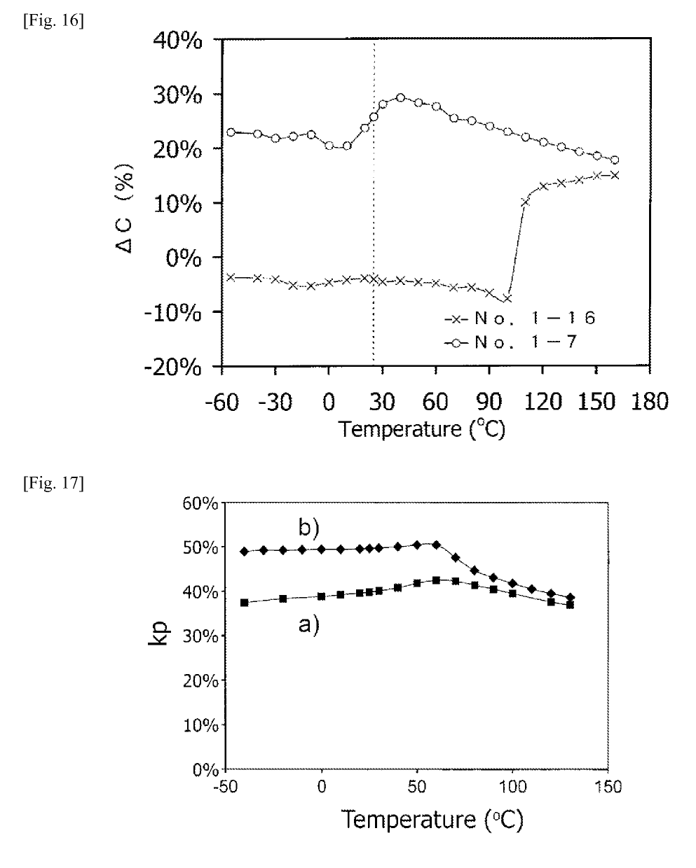

Also, to evaluate that sudden change in capacitance across the crystal-structure transition point could be reduced, samples of the compositions listed in Table 1 were evaluated for temperature dependence of capacitance change before and after polarization using the aforementioned method. To indicate the effects of the present invention more specifically, temperature characteristics of the capacitance after polarization process (Ca) and capacitance before polarization process (Cb), of Sample No. 1-7 included in the scope of the present invention, are shown in FIG. 14. As a comparative example, temperature characteristics of the capacitance after polarization process (Ca) and capacitance before polarization process (Cb), of Sample No. 1-16 having a conventional crystal-structure transition point, are shown in FIG. 15. Additionally, a comparison of the rates of change in capacitance (AC) before and after polarization of Sample Nos. 1-7 and 1-16 is shown in FIG. 16.

If ΔC>0 was always satisfied in a temperature range of −50° C. to 150° C., the result was indicated as “Satisfied,” while, when the condition was not met in this temperature range, the result was indicated as “Not satisfied,” and the results of the samples produced in this example are summarized in Table 4.

Additionally, piezoelectric characteristics of the polarized samples whose composition formulas are shown in Table 1, were measured in the form of electromechanical coupling constant kp to check if enough piezoelectric characteristics to withstand practical applications were retained. These results are also shown in Table 4.

The following paragraphs explain the structural changes occurring at the crystal-structure transition point and also describe how presence or absence of a monoclinic crystal structure of Z=1 at −50° C. to 150° C., as stated in Table 4, was determined.

First, Sample No. 1-1, which is a comparative example, was determined to have undergone a change from the orthorhombic crystal structure of Z=2 and having symmetry of Amm2 as shown in FIG. 3, to the tetragonal crystal structure of Z=1 and having symmetry of P4 mm as shown in FIG. 2, in a range of 190° C. to 220° C. To be specific, a) in FIG. 9 shows a representative X-ray diffraction profile of an orthorhombic perovskite crystal structure of Z=2 and having symmetry of Amm2, while d) in FIG. 9 and e) in FIG. 9 each show a representative X-ray diffraction profile of an orthorhombic perovskite crystal structure of Z=1 and having symmetry of P4 mm. b) in FIG. 9 and c) in FIG. 9 were determined to be showing a transient state of crystal structure transition.

Accordingly, Sample No. 1-1, which is a comparative example, is clearly a composition outside the scope of the present invention because the crystal-structure transition point exists between 190° C. and 220° C. and the structural change at the crystal-structure transition point is from an orthorhombic crystal structure of Z=2 and having symmetry of Amm2 to a tetragonal crystal structure of Z=1 and having symmetry of P4 mm.

On the other hand, among the diffraction profiles relating to Sample No. 1-7, which is an example of the present invention, as shown in FIG. 10, the profiles observed at −50° C. to 0° C. are considered to represent a porcelain composition having an entirely different crystal system and space group, not an orthorhombic crystal structure of Z=2 and having symmetry of Amm2 as has been considered. If transition occurred from the orthorhombic crystal structure of Z=2 and having symmetry of Amm2 as shown in FIG. 10 to a tetragonal crystal structure of Z=1 and having symmetry of P4 mm, then a rectangular X-ray diffraction profile like the one in a) in FIG. 12 should be obtained. Looking at the diffraction profiles of Sample No. 1-7 in FIG. 10, however, a rectangular X-ray diffraction profile like the one in a) in FIG. 12 was not achieved, even at a temperature as low as −100° C., as shown in a) in FIG. 10 to c) in FIG. 10.

To be specific, an orthorhombic crystal structure of Z=2 and having symmetry of Amm2 should give two diffraction profiles in a range of 44°≦2θ≦47°, each looking like the rectangular X-ray diffraction profile shown in a) in FIG. 9, where a more intense X-ray diffraction peak exists on the low-angle side than on the high-angle side. However, such rectangular profile was not obtained.

After various considerations, and from the temperature behaviors of diffraction profiles derived from a perovskite structure shown in a) in FIG. 10 to k) in FIG. 10, a monoclinic crystal structure of Z=1 and having symmetry of Pm, where the symmetry is weaker than that of space group Amm2, as shown in FIG. 4, was determined. This is specifically because, with a monoclinic crystal structure of Z=1 and having symmetry of Pm, three diffraction profiles can exist in a range of 44°≦2θ≦47°, like the rectangular profiles shown in a) in FIG. 10 to 0k) in FIG. 10. On the other hand, a porcelain composition having a tetragonal crystal structure of Z=1 and having symmetry of P4 mm as traditionally considered, was confirmed in a range of 30° C. to 150° C. as shown in FIG. 10. In addition, the range of 0° C. to 30° C. shown in FIG. 9 was determined as a transient state of crystal structure transition.

From the above, the applicable transition point is one at which a monoclinic crystal structure of Z=1 and having symmetry of Pm changes to a tetragonal crystal structure of Z=1 and having symmetry of P4 mm, as mentioned above, and therefore it was determined that the orientation of spontaneous polarization could be fixed to the orientation of [001] across the crystal-structure transition point.

Also, to further evaluate the validity of the aforementioned judgment recognizing a monoclinic crystal structure of Z=1 and having symmetry of Pm, the judgment results of space groups and calculated results of lattice constants according to the Rietveld method, shown in Table 2 below, were used to conduct verification.

TABLE 2

| Sample | | Space | | | | |
|---|---|---|---|---|---|---|
| No. | Composition formula | group | a(Å) | b(Å) | c(Å) | β(°) |
| 1-5 | Li_{0.050}[Na_{0.50}K_{0.50}]_{0.950}NbO₃ | Pm | 3.9864(2) | 3.9431(1) | 4.0130(2) | 90.272(5) |
| 1-6 | Li_{0.055}[Na_{0.50}K_{0.50}]_{0.945}NbO₃ | Pm | 3.9815(2) | 3.9445(1) | 4.0215(2) | 90.210(6) |
| 1-7 | Li_{0.060}[Na_{0.50}K_{0.50}]_{0.940}NbO₃ | Pm | 3.9708(2) | 3.9505(1) | 4.0409(1) | 90.140(6) |

With Sample No. 1-5, the measured value and calculated value agreed best when the monoclinic crystal structure model of Z=1 and having symmetry of Pm was used. Since the lattice constants also had the relationships of a≠b≠c where β>90°, the results were determined appropriate.

Also with Sample No. 1-6, the measured value and calculated value agreed best when the monoclinic crystal structure model of Z=1 and having symmetry of Pm was used. Since the lattice constants also had the relationships of a≠b≠c where β>90°, the results were determined appropriate.

Again with Sample No. 1-7, the measured value and calculated value agreed best when the monoclinic crystal structure model of Z=1 and having symmetry of Pm was used. Since the lattice constants also had the relationships of a≠b≠c where β>90°, the results were determined appropriate.

However, the X-ray diffraction profiles of Sample No. 1-7 exhibit temperature dependence as shown in FIG. 10, where the range from 0° C. to 30° C. is considered a transient state of crystal structure transition, and the X-ray diffraction profiles taken at 30° C. or above were determined as representing the aforementioned tetragonal crystal structure of Z=1. Accordingly, the calculation results of lattice constants shown in Table 2 represent the results of calculation and measurement near the crystal-structure transition point and therefore the results may vary depending on the measurement method, sample shape, and so on. However, it was verified from the X-ray diffraction profiles in FIG. 10 that, even when the measured result and calculated result of Sample No. 1-7 differ and the result indicates the aforementioned tetragonal crystal structure of Z=1 and having symmetry of P4 mm, a monoclinic crystal structure of Z=1 and symmetry of Pm is still confirmed by measuring at lower temperatures.

Additionally, to further evaluate the validity of the aforementioned judgment recognizing a monoclinic crystal structure of Z=1 and having symmetry of Pm, the aforementioned HOLZ lines were analyzed to evaluate the space group and lattice constants of the crystal structure. This verification was performed using the results shown in Table 3 below.

TABLE 3

| Sample | | Space | | | | |
|---|---|---|---|---|---|---|
| No. | Composition formula | group | a(Å) | b(Å) | c(Å) | β(°) |
| 1-5 | Li_{0.050}[Na_{0.50}K_{0.50}]_{0.950}NbO₃ | Pm | 4.107(12) | 4.066(12) | 4.197(13) | 91.9(3) |
| 1-6 | Li_{0.055}[Na_{0.50}K_{0.50}]_{0.945}NbO₃ | Pm | 3.921(12) | 3.895(12) | 3.951(12) | 91.2(3) |
| 1-7 | Li_{0.060}[Na_{0.50}K_{0.50}]_{0.940}NbO₃ | P4mm | 4.000(12) | 3.994(12) | 4.044(12) | 90.1(3) |

The absolute values of lattice constants used in the above verification do not agree with the values in Table 2. This is because, in the evaluation of HOLZ lines appearing on the CBED pattern, the absolute values of calculated lattice constants are inevitably affected to a significant degree by the voltage of irradiated convergent electron beam, thickness and non-uniformity of thickness of the measured sample, and so on, and accordingly the ratios of lattice constants with the same sample should be discussed by sparing various discussions.

As for the results in Table 3 of Sample No. 1-5, the values of a, b and c varied more than the margin of error and β was comfortably determined as greater than 90°. Therefore, it was clearly appropriate to define the piezoelectric porcelain composition of Sample No. 1-5 as a monoclinic crystal structure model of Z=1 and having symmetry of Pm, also based on the TEM analysis result of the interior of each grain forming the piezoelectric porcelain composition.

As for the results in Table 3 of Sample No. 1-6, the values of a, b and c varied more than the margin of error and β was comfortably determined as greater than 90°. Therefore, it was clearly appropriate to define the piezoelectric porcelain composition of Sample No. 6 as a monoclinic crystal structure model of Z=1 and having symmetry of Pm, also based on the TEM analysis result of the interior of each grain forming the piezoelectric porcelain composition.

As for the results in Table 3 of Sample No. 1-7, it was concluded that, given the margin of error, a=b and β was 90°. Therefore, the piezoelectric porcelain composition of Sample No. 1-7 was defined as a tetragonal crystal structure model of Z=1 and having symmetry of P4 mm.

This result is different from the conclusion obtained from Table 2, but because it represents what is happening near the phase transition point as mentioned above, the difference may have been caused by the sample temperature rising to or beyond the crystal-structure transition point due to the effect of irradiated electron beam, etc., thereby causing the structure to change to the tetragonal system. As mentioned above, it was verified from the X-ray diffraction profiles in FIG. 10 that a monoclinic crystal structure of Z=1 and symmetry of Pm is still confirmed by measuring at lower temperatures, and consequently this result indicates presence of a monoclinic crystal structure of Z=1 and having symmetry of Pm at temperatures lower than room temperature.

By verifying the above results shown in Tables 2 and 3, it was shown more clearly that the piezoelectric porcelain composition conforming to the present invention is a piezoelectric porcelain composition that can transition from a monoclinic crystal structure of Z=1 and having symmetry of Pm to a tetragonal crystal structure of Z=1 and having symmetry of P4 mm.

Note that, while the above verification used piezoelectric porcelain compositions that could take on a monoclinic crystal structure model of Z=1 and having symmetry of Pm at temperatures around room temperature, as these compositions are particularly useful in discussing the present invention in a clear, easy manner, similar verification results can be obtained by verifying piezoelectric porcelain compositions within the scope of the present invention through similar operations as deemed appropriate in a temperature range of −50° C. to 150° C.

Now, the following sections explain the temperature dependence of measured change in capacitance using the results in FIG. 14 indicating the temperature dependence of the capacitance after polarization process (Ca) and capacitance before polarization process (Cb), of Sample No. 1-7 which is an example of the present invention, results in FIG. 15 indicating the temperature dependence of the capacitance after polarization process (Ca) and capacitance before polarization process (Cb), of Sample No. 1-16 which is a comparative example, and FIG. 16 showing, for each of these samples, the temperature dependence of the rate of change in capacitance (ΔC) before and after polarization.

According to FIG. 14, the piezoelectric porcelain composition of Sample No. 1-7 which is an example of the present invention always satisfies Ca>Cb at each temperature from −50° C. to 150° C., and therefore ΔC shown in FIG. 16 satisfies ΔC>0. As a result, the change in capacitance after polarization was reduced and became gradual as evident from the values before and after the crystal-structure transition point (around 25° C.).

According to FIG. 15, the piezoelectric porcelain composition of Sample No. 1-16 which is a comparative sample satisfies Ca>Cb at temperatures higher than the crystal-structure transition point (around 110° C.), but the relationship is Ca<Cb at temperatures lower than this point. Accordingly, ΔC shown in FIG. 16 satisfies ΔC>0 at temperatures higher than the crystal-structure transition point, but the relationship is ΔC<0 at temperatures lower than this point. For this reason, the change in capacitance after polarization inevitably became sudden as evident from the values before and after the crystal-structure transition point.

As explained above, the piezoelectric porcelain composition within the scope of the example of the present invention had characteristics to reduce sudden change in capacitance after polarization across the crystal-structure transition point. This is due to the different orientations in which the crystal system can undergo spontaneous polarization before and after the crystal-structure transition point, as mentioned above.

Based on the foregoing, including the detailed change in the crystal system at the crystal-structure transition point, validity of the judgment that a monoclinic crystal structure of Z=1 and having symmetry of Pm exists on the lower-temperature side of the transition point, verification of a higher electromechanical coupling constant (kp) resulting from the MPB existing in a range of −50° C. to 150° C. due to the crystal-structure transition point, the fact that sudden change in capacitance at the crystal-structure transition point can be reduced after the polarization process due to presence of a monoclinic crystal structure of Z=1 and having symmetry of PM on the lower-temperature side of the crystal-structure transition point, and each example, the effects of the present invention are conclusively explained using Table 4 with respect to the piezoelectric porcelain compositions of the examples of the present invention.

TABLE 4

| | | Monoclinic crystal | |
|---|---|---|---|
| | | structure of Z = 1 | ΔC > 0 satisfied/not |
| Sample | Electromechanical | present/absent at | satisfied at |
| No. | coupling constant | −50° C. to 150° C. | −50° C. to 150° C. |
| *1-1 | 35 | Absent | Not satisfied |
| *1-2 | 42 | Absent | Not satisfied |
| 1-3 | 42 | Present | Satisfied |
| 1-4 | 41 | Present | Satisfied |
| 1-5 | 45 | Present | Satisfied |
| 1-6 | 44 | Present | Satisfied |
| 1-7 | 43 | Present | Satisfied |
| 1-8 | 37 | Present | Satisfied |
| *1-9 | 28 | Absent | Satisfied |
| 1-10 | 43 | Present | Satisfied |
| 1-11 | 43 | Present | Satisfied |
| 1-12 | 42 | Present | Satisfied |
| *1-13 | 36 | Absent | Not satisfied |
| 1-14 | 44 | Present | Satisfied |
| 1-15 | 39 | Present | Satisfied |
| *1-16 | 35 | Absent | Not Satisfied |
| 1-17 | 40 | Present | Satisfied |
| 1-18 | 48 | Present | Satisfied |
| 1-19 | 47 | Present | Satisfied |
| *1-20 | 41 | Absent | Not satisfied |
| 1-21 | 44 | Present | Satisfied |
| 1-22 | 47 | Present | Satisfied |
| 1-23 | 42 | Present | Satisfied |

As for Sample Nos. 1-1 to 1-9, the results are based on adjustment of x in a condition where y=0.50, z=0.0 and w=0.0.

It is shown that, in this case, particularly when the kp indicator of piezoelectric characteristics is high and ΔC>0 is satisfied at −50 to 150° C., the aforementioned monoclinic crystal structure of Z=1 exists at −50° C. to 150° C. Accordingly, Sample Nos. 3 to 8 are clearly compositions within the scope of the present invention.

Also, as mentioned above, presence of a monoclinic system of Z=1 was evaluated for Sample Nos. 1-5, 1-6 and 1-7, particularly through the crystal structure model evaluation at 25° C. according to the Rietveld method, calculation of lattice constants, CBED pattern by TEM, and calculated results of lattice constants from the HOLZ lines appearing on this pattern.

Also, as mentioned above, FIG. 14 shows the temperature dependence of capacitance before and after polarization, while FIG. 16 shows ΔC, for Sample No. 1-7.

As for Sample No. 1-1, where x=0.00, the crystal-structure transition point exists between 190° C. and 230° C. as shown in FIG. 9, but not between −50° C. and 150° C., and therefore this composition was excluded from the scope of the present invention.

As for Sample No. 1-2, where x=0.02 and Li is added to the A site as a solid solution, the crystal-structure transition point exists at temperatures lower than the range of 190° C. to 230° C. applicable to Sample No. 1, but not between −50° C. and 150° C. Also, an orthorhombic system of Z=2 having symmetry of Amm2 was identified on the lower-temperature side of the crystal-structure transition point. Accordingly, this composition was excluded from the scope of the present invention.

As for Sample No. 1-9, which satisfies ΔC>0 at −50° C. to 150° C., the aforementioned crystal-structure transition point is not adjusted to within a range of −50° C. to 150° C. and therefore the kp indicator of piezoelectric characteristics is low, and accordingly this composition was excluded from the scope of the present invention.

As for Sample Nos. 1-10 to 1-16, the results are based on adjustment of y in a condition where x=0.06, z=0.0 and w=0.0. It is shown that, in this case, too, the aforementioned monoclinic crystal structure of Z=1 exists at −50° C. to 150° C. when kp is high and ΔC>0 is satisfied at −50 to 150° C. Accordingly, Sample Nos. 1-10 to 1-12, 1-14 and 1-15 are clearly compositions within the scope of the present invention.

As for Sample Nos. 1-13 and 1-16, it is shown that the aforementioned monoclinic crystal structure of Z=1 does not exist at −50° C. to 150° C. and ΔC>0 is not satisfied at −50° C. to 150° C., either, and accordingly this composition was excluded from the scope of the present invention.

As for Sample Nos. 1-17 to 1-23, the results are based on adjustment of x, z and w in various ways at y=0.50. It is shown that, in this case, too, ΔC>0 is satisfied at −50° C. to 150° C. when kp is high and the aforementioned monoclinic crystal structure of Z=1 exists at −50° C. to 150° C. Accordingly, Sample Nos. 17 to 19 and 21 to 23 are clearly compositions within the scope of the present invention.

As for Sample No. 1-20, it is shown that the aforementioned monoclinic crystal structure of Z=1 does not exist at −50° C. to 150° C. and ΔC>0 is not satisfied at −50° C. to 150° C., either, and accordingly this composition was excluded from the scope of the present invention.

As described above, a piezoelectric porcelain composition according to the present invention reduces sudden change in capacitance while having a crystal-structure transition point within the operation guaranteed temperature range, and therefore such piezoelectric porcelain composition provides a piezoelectric ceramic component or piezoelectric device whose operation can be guaranteed over a wide temperature range while maintaining high piezoelectric characteristics using the MPB, and which can ultimately substitute a lead-based piezoelectric device that uses PbO having high environmental burdens.

### Example 2

In this example, differences arising from the crystal system present at the time of polarization process were examined.

Here, piezoelectric porcelain composition samples polarized at a temperature associated with the tetragonal system, and piezoelectric porcelain composition samples polarized at a temperature associated with the monoclinic system, were prepared as porcelain composition samples subjected to the polarization process. Specifically when the composition formula Li_{0.054}(Na_{0.50}K_{0.50})_{0.946}NbO₃ is used, for example, the crystal system can be controlled according to the polarization temperature because it is monoclinic at 25° C. and tetragonal at 150° C.

Table 5 summarizes the piezoelectric porcelain compositions prepared. In the table, samples polarized at a temperature associated with the monoclinic system (25° C. in this example) are differentiated from the samples polarized at a temperature associated with the tetragonal system (150° C. in this example) by adding “#” in front of the sample number for the latter. Note that in Table 5 the samples whose sample number is accompanied by * are compositions outside the scope of the present invention.

TABLE 5

| Sample No. | x | Y | z | W | Polarized crystal system |
|---|---|---|---|---|---|
| *2-1 | 0.00 | 0.50 | 0.0 | 0.0 | Orthorhombic system |
| 2-2 | 0.05 | 0.50 | 0.0 | 0.0 | Monoclinic system |
| #2-3 | 0.05 | 0.50 | 0.0 | 0.0 | Tetragonal system |
| 2-4 | 0.052 | 0.50 | 0.0 | 0.0 | Monoclinic system |
| #2-5 | 0.052 | 0.50 | 0.0 | 0.0 | Tetragonal system |
| 2-6 | 0.054 | 0.50 | 0.0 | 0.0 | Monoclinic system |
| #2-7 | 0.054 | 0.50 | 0.0 | 0.0 | Tetragonal system |
| 2-8 | 0.056 | 0.50 | 0.0 | 0.0 | Monoclinic system |
| #2-9 | 0.056 | 0.50 | 0.0 | 0.0 | Tetragonal system |
| 2-10 | 0.058 | 0.50 | 0.0 | 0.0 | Monoclinic system |
| #2-11 | 0.058 | 0.50 | 0.0 | 0.0 | Tetragonal system |
| 2-12 | 0.06 | 0.50 | 0.0 | 0.0 | Monoclinic system |
| #2-13 | 0.06 | 0.50 | 0.0 | 0.0 | Tetragonal system |
| 2-14 | 0.06 | 0.40 | 0.0 | 0.0 | Monoclinic system |
| #2-15 | 0.06 | 0.40 | 0.0 | 0.0 | Tetragonal system |
| 2-16 | 0.04 | 0.60 | 0.0 | 0.0 | Monoclinic system |
| #2-17 | 0.04 | 0.60 | 0.0 | 0.0 | Tetragonal system |
| 2-18 | 0.03 | 0.50 | 0.20 | 0.0 | Monoclinic system |
| #2-19 | 0.03 | 0.50 | 0.20 | 0.0 | Tetragonal system |
| 2-20 | 0.05 | 0.50 | 0.0 | 0.05 | Monoclinic system |
| #2-21 | 0.05 | 0.50 | 0.0 | 0.05 | Tetragonal system |
| 2-22 | 0.04 | 0.50 | 0.10 | 0.04 | Monoclinic system |
| #2-23 | 0.04 | 0.50 | 0.10 | 0.04 | Tetragonal system |

Next, the prepared samples were measured for resonance-antiresonance according to the aforementioned evaluation method within a range of −40° C. to 130° C. to calculate, among other piezoelectric characteristics, the electromechanical coupling constant kp in the surface expanding direction of the disk-shaped vibrator. As examples, the measured results of Sample Nos. 2-6 and #2-7 are shown in FIG. 17. In the graph, a) indicates the measured results of Sample No. #2-7, while b) indicates the measured results of Sample No. 2-6.

Also, to observe the condition of orientation in which the crystal was polarized by the polarization process, the orientation condition was checked using the aforementioned X-ray diffraction method.

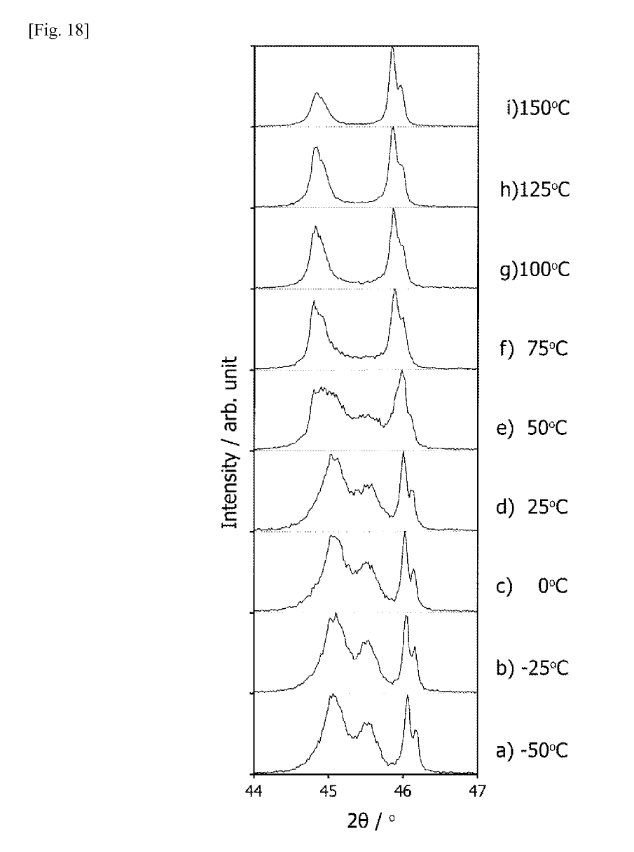

As examples, the measured results of Sample Nos. 2-6 and #2-7 based on the composition formula Li_{0.054}(Na_{0.50}K_{0.50})_{0.946}NbO₃, or specifically the sample in a non-polarized state, sample in a state after the polarization process at the monoclinic system (No. 2-6) and sample in a state after the polarization process at the tetragonal system (No. #2-7), are shown in FIGS. 18 to 20, respectively.

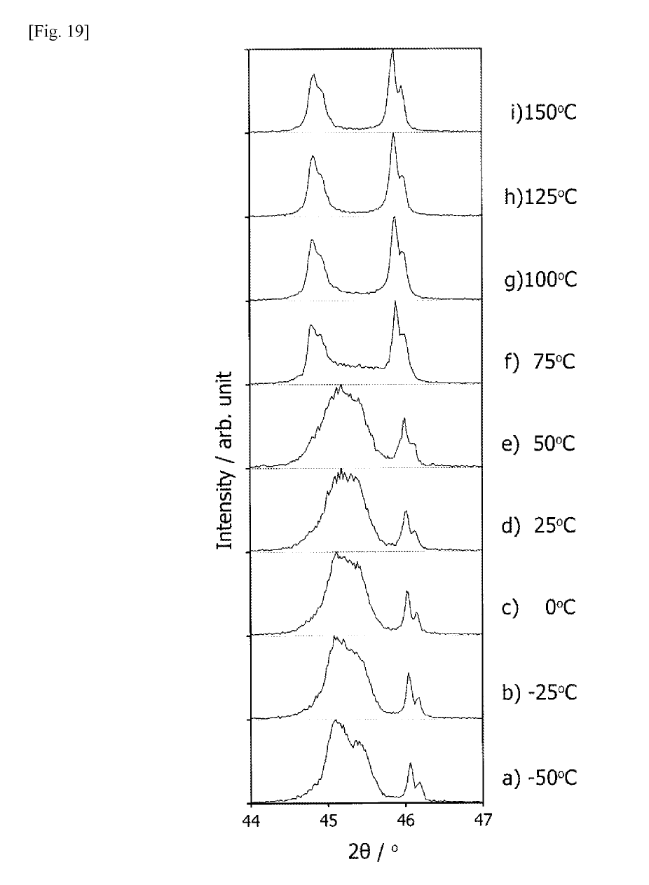

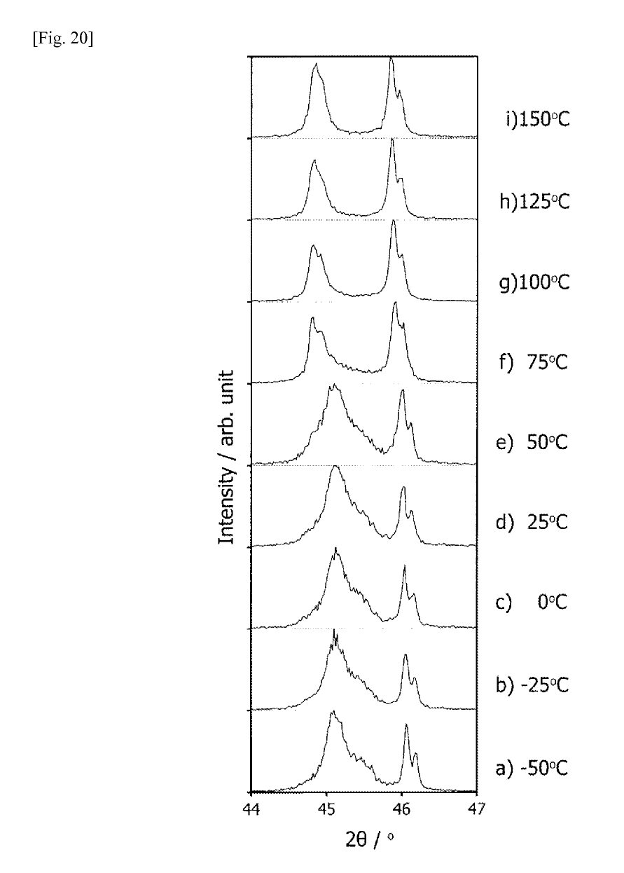

FIGS. 21 to 23 are enlarged views of the 200, 020 and 002 diffraction lines present in a range of 44°≦2θ≦47° in the X-ray diffraction profiles measured at −25° C., 25° C. and 125° C. as shown in FIGS. 18 to 20. Among these graphs, a) corresponds to FIG. 18, b) corresponds to FIG. 19, and c) corresponds to FIG. 20.

The profiles in FIGS. 18 and 19 and enlarged profiles in FIGS. 21 to 23 reveal that, when the polarization process is performed at the monoclinic system, the intensity of h00 increases relative to 0k0 and intensity of 001 also increases relative to 0k0, in a range of −50° C. to 75° C. associated with the monoclinic system, when compared with the non-polarized state. This means that the applicable domain is oriented in the orientation of <101>.

The profiles in FIGS. 18 and 20 and enlarged profiles in FIGS. 21 to 23 reveal that, when the polarization process is performed at the tetragonal system, the intensity of h00 decreases relative to 0k0 while the intensity of 001 increases relative to 0k0, in a range of −50° C. to 75° C. associated with the monoclinic system, when compared with the non-polarized state. This means that the applicable domain is oriented in the orientation of <001>. Accordingly, the applicable domain is not oriented in the orientation of <100>.

Also based on the measured results of all samples shown in Table 5, it was found that the intensity of h00 increases relative to 0k0 and the intensity of 001 also increases relative to 0k0, when the polarization process is performed at the monoclinic system, as mentioned above, which means that the applicable domain structure is oriented in the orientation of <101>. Similarly it was also found that when the polarization process is performed at the tetragonal system, the intensity of h00 decreases relative to 0k0 while the intensity of 001 increases relative to 0k0, in a range of −50° C. to 75° C. associated with the monoclinic system, when compared with the non-polarized state, which means that the applicable domain structure is oriented in the orientation of <001>. Accordingly, the applicable domain structure is not oriented in the orientation of <100>.

In the foregoing, the constants of crystal orientation <u v w> assume a monoclinic perovskite structure with a molecular number of 1 (Z=1) whose crystal axes are c>a>b and one of their inter-axis angles β satisfies β>90°.

To quantify the differences between samples expressed by the same composition formula but subjected to different polarization processes, I (200), I (020) and I (002) were used as indicators among the X-ray diffraction line intensities I (h00), I (0k0) and I (001) relating to the surface indexes h00, 0k0 and 001 belonging to the crystal orientations <100>, <010> and <001> when there is a monoclinic perovskite structure with a molecular number of 1 (Z=1) whose crystal axes lengths are c>a>b and one of their inter-axis angles β satisfies β>90°, and when the following formula was satisfied, orientation in the orientation of <100> was recognized:

[I(200)/I(020)]/[I₀(200)/I₀(020)]<1 Formula (1)

Here, I₀ (200)/I₀ (020) represents the ratio of X-ray diffraction line intensities as defined by the surface indexes 200 and 020 in a non-polarized state, measured by the same method used to measure I (200)/I (020).

Similarly, when the following formula was satisfied, orientation in the orientation of <001> was recognized:

[I(002)/I(020)]/[I₀(002)/I₀(020)]>1 Formula (2)

Here, I₀ (002)/I₀ (020) represents the ratio of X-ray diffraction line intensities as defined by the surface indexes 002 and 020 in a non-polarized state, measured by the same method used to measure I (002)/I (020).

Table 6 summarizes the measured results of orientation condition according to Formulas (1) and (2), of Sample Nos. 2-6 and #2-7 based on the composition formula Li_{0.054}(Na_{0.50}K_{0.50})_{0.946}NbO₃, or specifically the sample in a non-polarized state, sample in a state after the polarization process at the monoclinic system (No. 2-6) and sample in a state after the polarization process at the tetragonal system (No. #2-7).

TABLE 6

| | Results of | | | Results of | | | Results in | | |
|---|---|---|---|---|---|---|---|---|---|
| Temperature | Sample No. #2-7 | | | Sample No. #2-6 | | | non-polarized state | | |
| (° C.) | I(002) | I(200) | I(020) | I(002) | I(200) | I(020) | I₀(002) | I₀(200) | I₀(020) |
| −50 | 359 | 153 | 473 | 678 | 408 | 409 | 547 | 345 | 738 |
| −25 | 413 | 98 | 425 | 627 | 366 | 450 | 525 | 349 | 737 |
| 0 | 406 | 124 | 397 | 582 | 370 | 422 | 473 | 314 | 672 |
| 25 | 404 | 106 | 390 | 494 | 422 | 339 | 423 | 277 | 646 |
| 50 | 360 | 41 | 418 | 462 | 142 | 360 | 292 | 174 | 560 |
| 75 | 458 | — | 658 | 538 | — | 755 | 689 | — | 924 |
| 100 | 640 | — | 969 | 781 | — | 1180 | 875 | — | 1204 |
| 125 | 656 | — | 952 | 1040 | — | 1404 | 944 | — | 1300 |
| 150 | 644 | — | 726 | 1024 | — | 1463 | 847 | — | 2240 |

| Left-term values of judgment formulas | | | |
|---|---|---|---|
| Formula | Formula | Formula | Formula |
| (1) | (2) | (1) | (2) |
| 1.02 | 0.69 | 2.24 | 2.13 |
| 1.36 | 0.49 | 1.95 | 1.71 |
| 1.45 | 0.67 | 1.96 | 1.88 |
| 1.58 | 0.63 | 2.22 | 2.90 |
| 1.65 | 0.32 | 2.47 | 1.27 |
| 0.94 | — | 0.96 | — |
| 0.91 | — | 0.91 | — |
| 0.95 | — | 1.02 | — |
| 2.35 | — | 1.85 | — |

As shown in Table 6, Sample No. #2-7 polarized at the tetragonal system always met Judgment Formula (1) for polarization orientation at −50 to 150° C. when an XRD pattern associated with the monoclinic system of Z=1 was observed.

On the other hand, Sample No. 2-6 polarized at the monoclinic system did not always meet Judgment Formula (1) for polarization orientation.

The above results indicate that the polarized state can be controlled according to the crystal system at the time of polarization and that, when polarization is performed at the tetragonal system, the polarization orientation of <001> can always be achieved.

The different temperature dependences of piezoelectric characteristics and electromechanical coupling constant (kp) in the diameter direction of the disk as shown in FIG. 17 are due to differences in this polarization orientation, and temperature dependence can clearly be reduced by adjusting the polarization orientation to <001>.

Table 7 shows the results of determining the polarization orientation for the samples in Table 5 based on the XRD patterns shown in FIGS. 18 to 20.

TABLE 7

| | Electromechanical | | kp dropping by | | | |
|---|---|---|---|---|---|---|
| Sample | coupling | Polarization | 20% or more due | Formula (1) | Formula (1′) | Formula (2) |
| No. | coefficient kp (%) | phase θ (°) | to temperature? | satisfied? | satisfied? | satisfied? |
| *2-1 | 0.41 | +83 | — | — | — | — |
| 2-2 | 0.50 | +85 | Dropped | Satisfied | Not satisfied | Satisfied |
| #2-3 | 0.40 | +78 | Did not drop | Not satisfied | Satisfied | Satisfied |
| 2-4 | 0.49 | +84 | Dropped | Satisfied | Not satisfied | Satisfied |
| #2-5 | 0.40 | +77 | Did not drop | Not satisfied | Satisfied | Satisfied |
| 2-6 | 0.49 | +83 | Dropped | Satisfied | Not satisfied | Satisfied |
| #2-7 | 0.40 | +77 | Did not drop | Not satisfied | Satisfied | Satisfied |
| 2-8 | 0.47 | +83 | Dropped | Satisfied | Not satisfied | Satisfied |
| #2-9 | 0.39 | +77 | Did not drop | Not satisfied | Satisfied | Satisfied |
| 2-10 | 0.46 | +81 | Dropped | Satisfied | Not satisfied | Satisfied |
| #2-11 | 0.41 | +78 | Did not drop | Not satisfied | Satisfied | Satisfied |
| 2-12 | 0.45 | +78 | Dropped | Satisfied | Not satisfied | Satisfied |
| #2-13 | 0.40 | +74 | Did not drop | Not satisfied | Satisfied | Satisfied |
| 2-14 | 0.52 | +86 | Dropped | Satisfied | Not satisfied | Satisfied |
| #2-15 | 0.47 | +81 | Did not drop | Not satisfied | Satisfied | Satisfied |
| 2-16 | 0.45 | +81 | Dropped | Satisfied | Not satisfied | Satisfied |
| #2-17 | 0.39 | +75 | Did not drop | Not satisfied | Satisfied | Satisfied |
| 2-18 | 0.52 | +81 | Dropped | Satisfied | Not satisfied | Satisfied |
| #2-19 | 0.48 | +78 | Did not drop | Not satisfied | Satisfied | Satisfied |
| 2-20 | 0.50 | +75 | Dropped | Satisfied | Not satisfied | Satisfied |
| #2-21 | 0.45 | +69 | Did not drop | Not satisfied | Satisfied | Satisfied |
| 2-22 | 0.48 | +73 | Dropped | Satisfied | Not satisfied | Satisfied |
| #2-23 | 0.46 | +67 | Did not drop | Not satisfied | Satisfied | Satisfied |

1. The samples indicated by * are compositions outside the scope of the present invention. Also note that Sample No. 2-1 does not meet the measurement conditions because it has an orthorhombic crystal structure.

According to the results in Table 7, clearly the drop from the maximum value to minimum value was −20% or less with the samples meeting the conditions of Formulas (1) and (2), which underwent the same processes except for the polarization process.

This clearly shows that, by controlling the polarization orientation, temperature dependence of electromechanical coupling coefficient can be reduced while keeping the MPB in a practical temperature zone of, for example, −50° C. to 150° C.

### Example 3

Table 7 summarizes the calculated results of electromechanical coupling constant Kp at room temperature (25° C.), polarization phases, and oriented states of samples as specified by Formulas (1′) and (2) below, of the samples shown in Table 5:

[I(200)/I(020)]/[I₀(200)/I₀(020)]>1 Formula (1′)

[I(002)/I(020)]/[I₀(002)/I₀(020)]>1 Formula (2)

According to the results in Table 7, the samples meeting the conditions of Formulas (1′) and (2), which underwent the same processes except for the polarization process, achieved a dramatically higher electromechanical coupling constant (such as kp) compared to the samples that met the condition of Formula (1′) but not the condition of Formula (2), and therefore this example clearly shows that the former samples had sufficient piezoelectric characteristics to substitute lead.

This example finds that a piezoelectric porcelain composition according to the present invention, which is a piezoelectric porcelain composition prepared in a straightforward manner without giving any consideration, such as the one expressed by, for example, the composition formula {Li_{z}[Na_{1-y}K_{y}]_{1-z}}ᵢ{Nb_{1-z-w}Ta_{z}Sb_{w}}ⱼO₃, can achieve a dramatically higher electromechanical coupling constant when the crystal system at the time of polarization is considered.

Specifically, this is probably because, by performing the polarization process at the aforementioned crystal system defined as monoclinic, the domain structure was oriented in an orientation not possible by the polarization processes performed in the aforementioned patent literatures and non-patent literatures.

Furthermore, similar experiments conducted on polarized piezoelectric porcelain compositions within the scope of the present invention found that a dramatically higher electromechanical coupling constant would also be achieved.

It is also found that, when a piezoelectric porcelain composition within the scope of the present invention is put through a polarization process at the tetragonal perovskite structure and then an electric field strength equal to or greater than the coercive electric field at which polarization occurs is applied to the composition in a state of monoclinic perovskite structure, it becomes a polarized piezoelectric porcelain composition within the scope of the present invention.

This shows that, when an electric field strength equal to or greater than the coercive electric field is applied to a piezoelectric ceramic component characterized by being formed by a piezoelectric porcelain composition according to the present invention, or to a piezoelectric device using such piezoelectric ceramic component, it becomes a polarized piezoelectric porcelain composition within the scope of the present invention.

The foregoing explained piezoelectric porcelain compositions according to the present invention, but the present invention is not at all limited to the aforementioned examples and various changes can be made within the scope of the present invention.

1. (canceled)

2. (canceled)

3. (canceled)

4. A piezoelectric porcelain composition composed of Li, Na, K, Nb, Ta, Sb and O as primary constituent elements, and having an alkali-niobate-based perovskite structure,
wherein the composition has a transition point at which the crystal structure changes from a monoclinic system defined by space group Pm to a tetragonal system defined by space group P4 mm where the piezoelectric porcelain composition has an ABO₃ type perovskite structure as a unit lattice of Z=1 said composition being expressed by the composition formula {Liₓ[Na_{1-y}K_{y}]₁₋ₓ}ᵢ{Nb_{1-z-w}Ta_{z}Sb_{w}}ⱼO₃ (wherein, in the formula, 0.03≦x<0.1, 0.3<y<0.7, 0.0≦z<0.3, 0≦w≦0.10, 0.95≦i≦1.01 and 0.95≦j≦1.01),
wherein, provided that X-ray diffraction line intensities I (h00), I (0k0) and I (001) relating to surface indexes h00, 0k0 and 001 belonging to crystal orientations <100>, <010> and <001> at crystal axis lengths of c>a>b where one of their inter-axis angles β satisfies β>90° are measured in a condition where an electric field applied at the time of polarization process is vertical to a diffraction surface of the piezoelectric porcelain composition meeting Bragg's law, line intensity ratios I (h00)/I (0k0) and I (001)/I (0k0) of the X-ray diffraction of the piezoelectric porcelain composition after the polarization process meet the following, provided that h=k=1=m (m is an integer of 1 or greater):
[I(h00)/I(0k0)]/[I₀(h00)/I₀(0k0)]<1
[I(001)/I(0k0)]/[I₀(001)/I₀(0k0)]>1
wherein I₀ (h00), I₀ (0k0) and I₀ (001) represent X-ray diffraction line intensities relating to the surface indexes h00, 0k0 and 001 in a non-polarized state, and must be measured by the same method used to measure I (h00), I (0k0) and I (001).

5. A piezoelectric porcelain composition composed of Li, Na, K, Nb, Ta, Sb and O as primary constituent elements, and having an alkali-niobate-based perovskite structure,
wherein the composition has a transition point at which the crystal structure changes from a monoclinic system defined by space group Pm to a tetragonal system defined by space group P4 mm where the piezoelectric porcelain composition has an ABO₃ type perovskite structure as a unit lattice of Z=1 said composition being expressed by the composition formula {Liₓ[Na_{1-y}K_{y}]₁₋ₓ}ᵢ{Nb_{1-z-w}Ta_{z}Sb_{w}}ⱼO₃ (wherein, in the formula, 0.03≦x<0.1, 0.3<y<0.7, 0.0≦z<0.3, 0≦w≦0.10, 0.95≦i≦1.01 and 0.95≦j≦1.01),
wherein, provided that X-ray diffraction line intensities I (h00), I (0k0) and I (001) relating to surface indexes h00, 0k0 and 001 belonging to crystal orientations <100>, <010> and <001> at crystal axis lengths of c>a>b where one of their inter-axis angles β satisfies β>90° are measured in a condition where an electric field applied at the time of polarization process is vertical to a diffraction surface of the piezoelectric porcelain composition meeting Bragg's law, line intensity ratios I (h00)/I (0k0) and I (001)/I (0k0) of the X-ray diffraction of the piezoelectric porcelain composition after the polarization process meet the following wherein h=k=1=m (m is an integer of 1 or greater):
[I(h00)/I(0k0)]/[I₀(h00)/I₀(0k0)]>1
[I(001)/I(0k0)]/[I₀(001)/I₀(0k0)]>1
wherein I₀ (h00), I₀ (0k0) and I₀ (001) represent X-ray diffraction line intensities relating to the surface indexes h00, 0k0 and 001 in a non-polarized state, and must be measured by the same method used to measure I (h00), I (0k0) and I (001).

6. A piezoelectric ceramic component whose first electrode and second electrode are opposing each other via a piezoelectric ceramic layer, said piezoelectric ceramic component characterized in that the piezoelectric ceramic layer is formed by a piezoelectric porcelain composition according to claim 4.

7. A piezoelectric ceramic component having multiple layers of first electrodes and second electrodes that are alternately layered via a piezoelectric ceramic layer in between and also having a first terminal electrode electrically connected to the first electrodes and a second terminal electrode electrically connected to the second electrodes, said piezoelectric ceramic component characterized in that the piezoelectric ceramic layer is formed by a piezoelectric porcelain composition according to claim 4.

8. A piezoelectric ceramic component having a board with a piezoelectric ceramic layer and also having a first electrode and a second electrode positioned on top of the piezoelectric ceramic layer in an opposing manner, said piezoelectric ceramic component characterized in that the piezoelectric ceramic layer is formed by a piezoelectric porcelain composition according to claim 4.

9. A piezoelectric ceramic component having multiple layers of first electrodes and second electrodes that are alternately layered on a board with a piezoelectric ceramic layer and also having a first terminal electrode electrically connected to the first electrodes and a second terminal electrode electrically connected to the second electrodes, said piezoelectric ceramic component characterized in that the piezoelectric ceramic layer is formed by a piezoelectric porcelain composition according to claim 4.

10. A process for producing a piezoelectric ceramic component, characterized by comprising a step in which electrodes are formed on a piezoelectric ceramic layer which in turn is formed by a piezoelectric porcelain composition according to claim 4 and which can have an AN-PV structure being a monoclinic perovskite structure, after which an electric field is applied to perform polarization.

11. A piezoelectric ceramic component whose first electrode and second electrode are opposing each other via a piezoelectric ceramic layer, said piezoelectric ceramic component characterized in that the piezoelectric ceramic layer is formed by a piezoelectric porcelain composition according to claim 5.

12. A piezoelectric ceramic component having multiple layers of first electrodes and second electrodes that are alternately layered via a piezoelectric ceramic layer in between and also having a first terminal electrode electrically connected to the first electrodes and a second terminal electrode electrically connected to the second electrodes, said piezoelectric ceramic component characterized in that the piezoelectric ceramic layer is formed by a piezoelectric porcelain composition according to claim 5.

13. A piezoelectric ceramic component having a board with a piezoelectric ceramic layer and also having a first electrode and a second electrode positioned on top of the piezoelectric ceramic layer in an opposing manner, said piezoelectric ceramic component characterized in that the piezoelectric ceramic layer is formed by a piezoelectric porcelain composition according to claim 5.

14. A piezoelectric ceramic component having multiple layers of first electrodes and second electrodes that are alternately layered on a board with a piezoelectric ceramic layer and also having a first terminal electrode electrically connected to the first electrodes and a second terminal electrode electrically connected to the second electrodes, said piezoelectric ceramic component characterized in that the piezoelectric ceramic layer is formed by a piezoelectric porcelain composition according to claim 5.

15. A process for producing a piezoelectric ceramic component, characterized by comprising a step in which electrodes are formed on a piezoelectric ceramic layer which in turn is formed by a piezoelectric porcelain composition according to claim 5 and which can have an AN-PV structure being a monoclinic perovskite structure, after which an electric field is applied to perform polarization.
